(19) United States
(12) Patent Application Publication
(10) Pub. No.: US 2026/0282542 A1
(43) Pub. Date: Sep. 17, 2026

(54) SEMICONDUCTOR STRUCTURE AND METHOD FOR FORMING THE SAME

(71) Applicant: Taiwan Semiconductor Manufacturing Co., Ltd., Hsinchu (TW)

(72) Inventors: Guan-Lin CHEN, Hsinchu (TW); Chih-Hao WANG, Hsinchu (TW); Cheng-Ting CHUNG, Hsinchu (TW); Kuo-Cheng CHIANG, Hsinchu (TW); Shi Ning JU, Hsinchu (TW)

(73) Assignee: Taiwan Semiconductor Manufacturing Co., Ltd., Hsinchu (TW)

(21) Appl. No.: 19/277,859

(22) Filed: Jul. 23, 2025

Related U.S. Application Data
(60) Provisional application No. 63/772,099, filed on Mar. 14, 2025.

(51) Int. Cl. H10D 86/00; H01L 21/321; H01L 21/762; H10D 30/00; H10D 30/01; H10D 30/43; H10D 62/13; H10D 62/40; H10D 62/832; H10D 64/23; H10D 64/27; H10D 86/01

(52) U.S. Cl. CPC H10D 86/201; H10D 30/014; H10D 30/0191; H10D 30/43; H10D 30/502; H10D 62/151; H10D 62/405; H10D 62/832; H10D 64/256; H10D 64/518; H10D 86/01; H10P 52/403; H10P 90/1914; H10W 10/181

(57) ABSTRACT

An integrated circuit includes a transistor including a pair of source/drain regions and a plurality of stacked first channels extending in a first lateral direction between the pair of first source/drain regions. The integrated circuit includes a pair of gate spacer layers adjacent to the first channels and a gate metal between the pair of gate spacer layers and between the first channels. The gate metal has a first length in the first lateral direction between the gate spacer layers and a second length in the first lateral direction between the first channels. The first length is greater than the second length.

### BACKGROUND

There has been a continuous demand for increasing computing power in electronic devices including smart phones, tablets, desktop computers, laptop computers and many other kinds of electronic devices. Integrated circuits provide the computing power for these electronic devices. One way to increase computing power in integrated circuits is to increase the number of transistors and other integrated circuit features that can be included for a given area of semiconductor substrate.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventor's approach to the particular problem, which, in and of itself, may also be inventive.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B and FIGS. 2-32D are cross-sectional and top views of an integrated circuit at intermediate stages of a processing, in accordance with some embodiments.

FIGS. 1C-1E are illustrations of a unit cell of monocrystalline silicon, in accordance with some embodiments.

FIG. 33 is a flow diagram of a method for forming an integrated circuit, in accordance with some embodiments.

FIG. 34 is a flow diagram of a method for forming an integrated circuit, in accordance with some embodiments.

### DETAILED DESCRIPTION

In the following description, many thicknesses and materials are described for various layers and structures within an integrated circuit die. Specific dimensions and materials are given by way of example for various embodiments. Those of skill in the art will recognize, in light of the present disclosure, that other dimensions and materials can be used in many cases without departing from the scope of the present disclosure.

The following disclosure provides many different embodiments, or examples, for implementing different features of the described subject matter. Specific examples of components and arrangements are described below to simplify the present description. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “one embodiment” or “an embodiment” means that a particular feature, structure or characteristic described in connection with the embodiment is included in at least some embodiments. Thus, the appearances of the phrases “in one embodiment”, “in an embodiment”, or “in some embodiments” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

Embodiments of the present disclosure provide an integrated circuit including transistors with improved electrical characteristics. Embodiments of the present disclosure provide transistors in which an inner gate length is shorter than an outer gate length. This is accomplished by forming deep recesses in sacrificial dielectric nanostructures for formation of inner spacers. After formation of the recesses, the length of the sacrificial semiconductor nanostructures is less than the width of the sacrificial gate structures. When the sacrificial gate structures and the sacrificial dielectric nanostructures are subsequently removed entirely and replaced with gate metals, the result is that the inner gate length is less than the outer gate length. Embodiments of the present disclosure also provide different crystal orientations for the channels of P-type field effect transistor (PFET) and N-type field effect transistor (NFET) devices.

The reduced inner gate length helps reduce the undesirable short channel effect. The different crystal orientations for the PFET channels and the NFET channels help ensure that both the NFET charge carriers and the PFET charge carriers have strong mobility. The result is integrated circuits with dense arrays of properly functioning transistors with good conduction and switching characteristics. This leads to better performing devices and higher wafer yields.

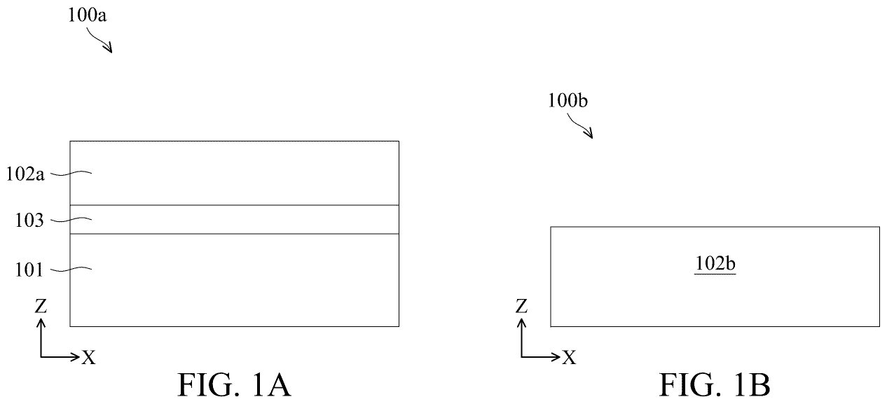

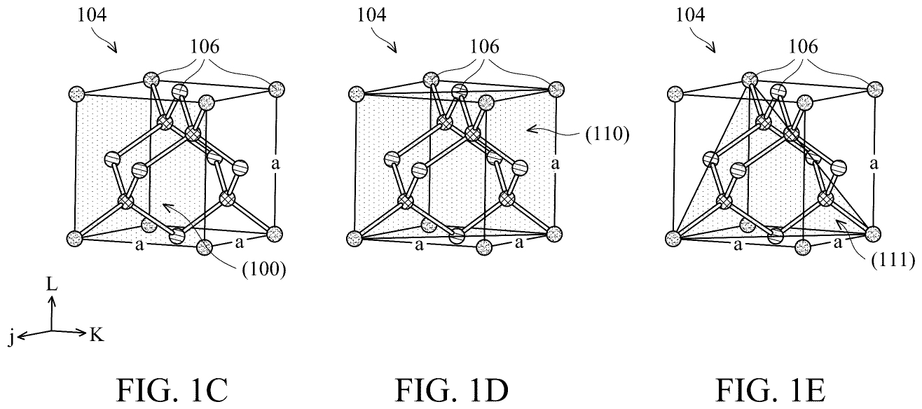

FIGS. 1A-1B and FIGS. 2A-17E are cross-sectional and top views of an integrated circuit at intermediate stages of a process for forming transistors an integrated circuit, in accordance with some embodiments.

The transistors may correspond to gate all around transistors. The gate all around transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the gate all around structure. Furthermore, the gate all around transistors may include a plurality of semiconductor nanostructures corresponding to channel regions of the transistors. The semiconductor nanostructures may include nanosheets, nanowires, or other types of nanostructures. The gate all around transistors may also be termed nanostructure transistors.

FIG. 1A is a cross-sectional view of a first wafer 100a including a semiconductor layer 101 and a semiconductor layer 102a. A semiconductor layer 103 is positioned on the first semiconductor layer 101 between the semiconductor layer 101 and the semiconductor layer 102a. The semiconductor layer 102a is also referred to as a semiconductor substrate because a stack of semiconductor layers will subsequently be grown from the semiconductor layer 102a, as will be set forth in more detail below.

The semiconductor layers 101 and 102a are a same semiconductor material. The semiconductor layer 103 is of a different material than the semiconductor layers 101 and 102a. In some embodiments, the semiconductor layer 101 is a monocrystalline semiconductor material including one or more of Si, Ge, SiGe, GaAs, InSb, GaP, GaSb, InAlAs, InGaAs, GaSbP, GaAsSb, InP or other suitable semiconductor materials. In an example illustrated herein, the substrates 101 and 102a each include monocrystalline silicon and the semiconductor layer 103 includes monocrystalline silicon germanium, though other materials can be utilized without departing from the scope of the present disclosure.

In some embodiments, the substrate 102a will be utilized to grow a stack of semiconductor layers that will be utilized for PFETs. The semiconductor layers will be grown with an epitaxial growth process from the substrate 102a. Accordingly, the semiconductor layers will carry a crystalline structure of the substrate 102a. In an example in which the semiconductor layers grown from the substrate 102a will be utilized to form channels of PFETs, it is beneficial to select an orientation of the crystalline structure of the substrate 102a to promote high mobility of holes (P-type charge carriers) traveling in the X-direction through the channels. As used herein, the orientation of the crystalline structure corresponds to the orientation at the X-Y plane of the exposed surface of the substrate 102a prior to growth of the epitaxial layers.

In some embodiments, the semiconductor layer 102a has a vertical thickness between 10 nm and 50 nm. The dielectric layer 112 has a vertical thickness between 5 nm and 30 nm. Other dimensions can be utilized without departing from the scope of the present disclosure.

FIG. 1B is a cross-sectional view of a second wafer 100b including a semiconductor substrate 102b. As will be set forth in more detail below, the wafers 100a and 100b will eventually be bonded together to form a compound wafer 105 in which the transistors are formed. In some embodiments, the semiconductor layer 102b has a vertical thickness between 10 nm and 50 nm.

In some embodiments, the semiconductor substrate 102b is a monocrystalline semiconductor material including one or more of Si, Ge, SiGe, GaAs, InSb, GaP, GaSb, InAlAs, InGaAs, GaSbP, GaAsSb, InP or other suitable semiconductor materials. In some embodiments, the semiconductor substrates 102a and 102b include a same semiconductor material. The substrates 102a and 102b can each include a monocrystalline semiconductor layer on at least a surface portion. In particular example given herein, the semiconductor substrates 102a and 102b are both monocrystalline silicon.

In some embodiments, the substrate 102b will be utilized to grow a stack of semiconductor layers that will be utilized for NFETs. The semiconductor layers will be grown with an epitaxial growth process from the substrate 102b. Accordingly, the semiconductor layers will carry a crystalline structure of the substrate 102b. In an example in which the semiconductor layers grown from the substrate 102b will be utilized to form channels of an NFET, it is beneficial to select the orientation of the crystalline structure of the substrate 102b to promote high mobility of electrons (N-type charge carriers) traveling in the X-direction through the channels. As used herein, the orientation of the crystalline structure corresponds to the orientation of the X-Y plane of the exposed surface of the substrate 102b prior to growth of the epitaxial layers. In some embodiments, the orientation of the crystalline structure of the substrate 102b is different than the orientation of the crystalline structure of the substrate 102a.

FIGS. 1C-1E are illustrations of a unit cell 104 of monocrystalline silicon. The unit cell 104 includes a plurality of silicon atoms 106. The unit cell 104 is cubic with sides of length a. In some embodiments, a has a value of 5.431 Å. FIGS. 1C-1E also utilize a coordinate system of three mutually orthogonal axes labeled j, k, and l. FIG. 1C illustrates the 100 plane. FIG. 1D illustrates the 110 plane. FIG. 1E illustrates the 111 plane.

The substrates 102a and 102b each have a crystal orientation, in accordance with some embodiments. The crystal orientation of the substrate corresponds to the plane (e.g., 100, 110, 111, etc.) that makes up the top surface (X-Y) plane of the substrate. In one example, NFET devices have a higher electron mobility in the X-direction when the silicon channels have a 100 orientation. In one example, PFET devices have a higher hole mobility in the X direction when the silicon channels have a 110 orientation. In some embodiments, the substrate 102a will be utilized for PFET devices and has a crystal orientation of 110. In some embodiments, the substrate 102b will be utilized for NFET devices, and has a crystal orientation of 100. Other materials and orientations can be utilized without departing from the scope of the present disclosure. In some embodiments, the semiconductor layer 101 has a crystal orientation of 110. In some embodiments, the substrate 102a has the crystal orientation 110 resulting from the crystal orientation 110 of the semiconductor layer 101 during the process for forming the substrate 102a.

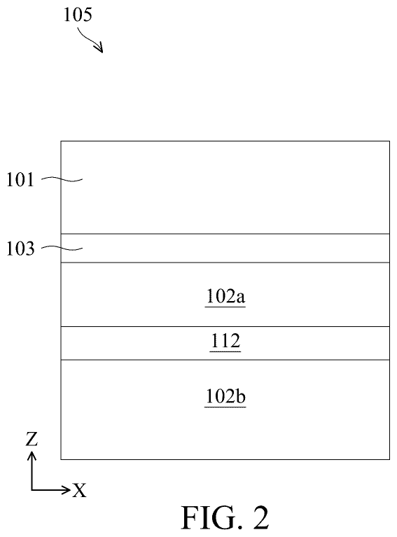

In FIG. 2, a bonding dielectric layer 112 has been formed on the semiconductor layer 102b, in accordance with some embodiments. The bonding dielectric layer 112 includes one or more of SiO, SiN, SiCN, SiOCN, or other suitable dielectric materials. The bonding dielectric layer 112 can be formed by atomic layer deposition (ALD), chemical vapor deposition (CVD), physical vapor deposition (PVD), or other suitable deposition processes. The bonding dielectric layer 112 may have a thickness between 10 nm and 30 nm, though other thicknesses can be utilized without departing from the scope of the present disclosure. In some embodiments, a portion of the bonding layer 112 is formed on both the semiconductor layer 102a and 102b prior to bonding the wafers 100a and 100b.

In FIG. 2, the wafers 100a and 100b have been bonded together to form a compound wafer 105, in accordance with some embodiments. The wafer 100a has been flipped so that the semiconductor substrate 102a faces downward. The wafers 100a and 100b are then stacked so that the bonding dielectric layer 112 is in contact with both the semiconductor substrate 102a and the semiconductor substrate 102b. As set forth previously, in some embodiments, separate portions of the bonding layer 112 are first deposited on the exposed surfaces of the semiconductor substrates 102a and 102b. The wafer 100a is then flipped and the bonding layer portions are brought together. Subsequently, a thermal annealing process is performed to bond the bonding dielectric layer portions to form the dielectric bonding layer 112 as shown in FIG. 2.

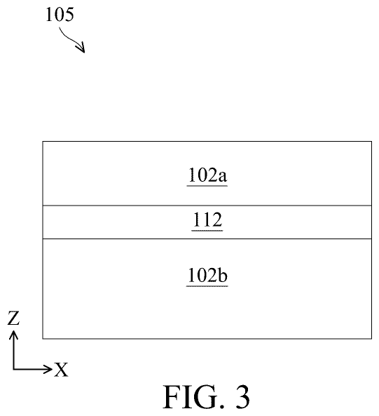

In FIG. 3, the semiconductor layers 101 and 103 have been removed from the compound wafer 105. Removal of the semiconductor layers 101 and 103 results in the top surface of the semiconductor substrate 102a exposed. In some embodiments, the removal process can include one or more of a grinding process, an etching process, and a CMP process. In some embodiments, the semiconductor layer 101 is first removed with a grinding process. The semiconductor layer 103 is then removed with an etching process that selectively etches the material of the semiconductor layer 103 with respect to the material of the semiconductor layer 102a.

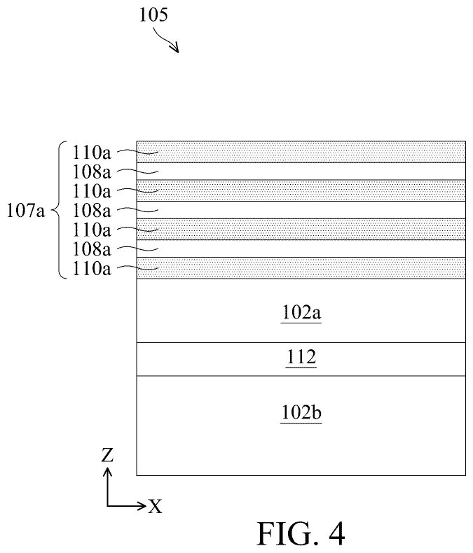

In FIG. 4, a stack 107a of semiconductor layers has been formed over the semiconductor substrate 102a, in accordance with some embodiments. The stack 107a can be formed by performing a series of epitaxial growth processes from the substrate 102a to form the layers of the stack 107a. The stack 107a includes a plurality of semiconductor layers 108a and sacrificial semiconductor layers 110a interleaved together. As will be set forth in more detail below, the semiconductor layers 108a will be patterned to form stacked channels of PFETs. As will be set forth in more detail below, the sacrificial semiconductor layers 110a will be patterned and eventually replaced with gate metals wrapped around the channels.

In some embodiments, the semiconductor layers 108a include silicon. Because the semiconductor layers 108a are grown epitaxially from the substrate 102a, the semiconductor layers 108a have a same crystal orientation (e.g., 110) as the substrate 102a. In some embodiments, the semiconductor layers 108a have a vertical thickness between 0.5 nm and 8 nm. Other materials, thicknesses, and orientations can be utilized without departing from the scope of the present disclosure.

In some embodiments, the sacrificial semiconductor layers 110a include a material that is selectively etchable with respect to the material of the semiconductor layers 108a. In some embodiments, the sacrificial semiconductor layers 110a include silicon germanium. Other materials can be utilized without departing from the scope of the present disclosure.

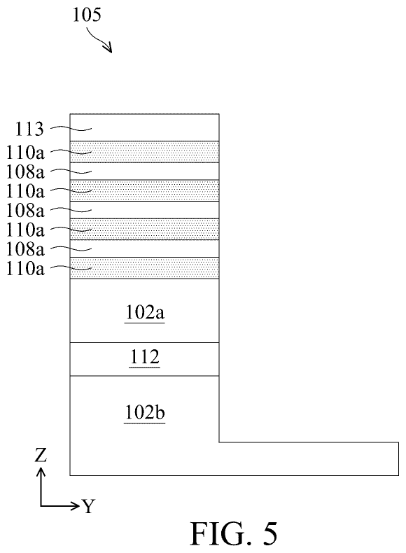

In FIG. 5 and etching process has been performed to expose the semiconductor substrate 102b at a portion of the wafer 105. In some embodiments, the etching process is performed to expose the semiconductor substrate 102b at the portion (or multiple separate portions) of the wafer at which N-type transistors will be formed. The etching process can include utilizing a photolithography process to form a patterned mask that covers the stack 107a at a portion (or portions) of the wafer 105 at which PFET devices will be formed. The patterned mask exposes the stack 107a at locations at which NFET devices will be formed. The etching process is then carried out. As can be seen, the etching process recesses the top surface of the semiconductor substrate 102b at the exposed locations.

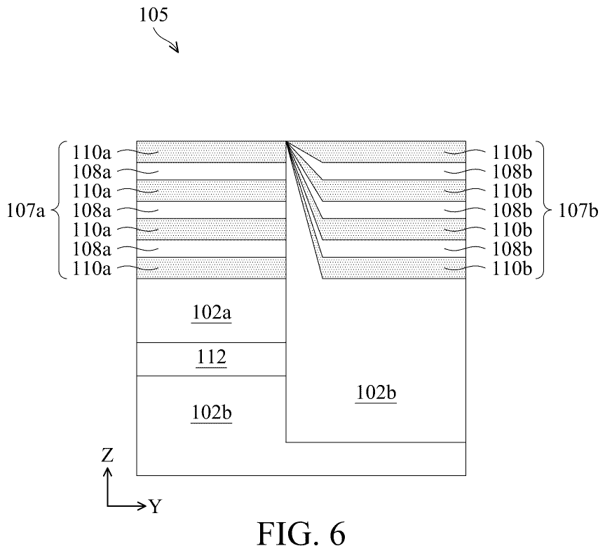

In FIG. 6, an epitaxial growth process has been performed to extend the top surface of the semiconductor substrate 102b substantially at a same height as the top surface of the semiconductor substrate 102a. The regrown portion of the substrate 102b may be considered a separate epitaxial semiconductor layer. In either case, the newly grown portion of the substrate 102b has the same crystal orientation as the substrate 102b (e.g., 100). A portion of the substrate 102b that abuts the substrate 102a and the stack 107a may have a slanted profile because some growth also occurs from the semiconductor substrate 102a and the stack 107a. However, this portion will subsequently be removed, as is set forth in more detail below. Alternatively, in some embodiments, a hard mask layer may be formed on the sidewalls stack 107a and the exposed sidewall of the semiconductor substrate 102a such that the subsequent epitaxial growth process from the substrate 102b does not include materials grown from the substrate 102a or the stack 107a.

In FIG. 6, a stack 107b of semiconductor layers has been formed over the substrate 102b at the exposed locations, in accordance with some embodiments. The stack 107b can be formed by performing a series of epitaxial growth processes from the substrate 102b to form the layers of the stack 107b. The stack 107b includes a plurality of semiconductor layers 108b and sacrificial semiconductor layers 110b interleaved together. As will be set forth in more detail below, the semiconductor layers 108b will be patterned to form stacked channels of NFET devices. As will be set forth in more detail below, the sacrificial semiconductor layers 110b will be patterned and eventually replaced with gate metals wrapped around the channels.

In some embodiments, the semiconductor layers 108b include silicon. Because the semiconductor layers 108b are grown epitaxially from the substrate 102b, the semiconductor layers 108b have a same crystal orientation (e.g., 100) as the substrate 102b. In some embodiments, the semiconductor layers 108 b have a vertical thickness between 0.5 nm and 8 nm. Other materials, thicknesses, and orientations can be utilized without departing from the scope of the present disclosure.

In some embodiments, the sacrificial semiconductor layers 110b include a material that is selectively etchable with respect to the material of the semiconductor layers 108b. In some embodiments, the sacrificial semiconductor layers 110b include silicon germanium. Other materials can be utilized without departing from the scope of the present disclosure.

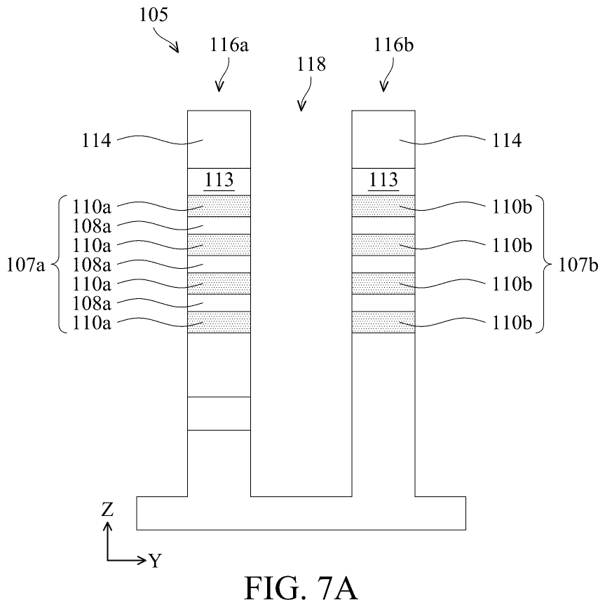

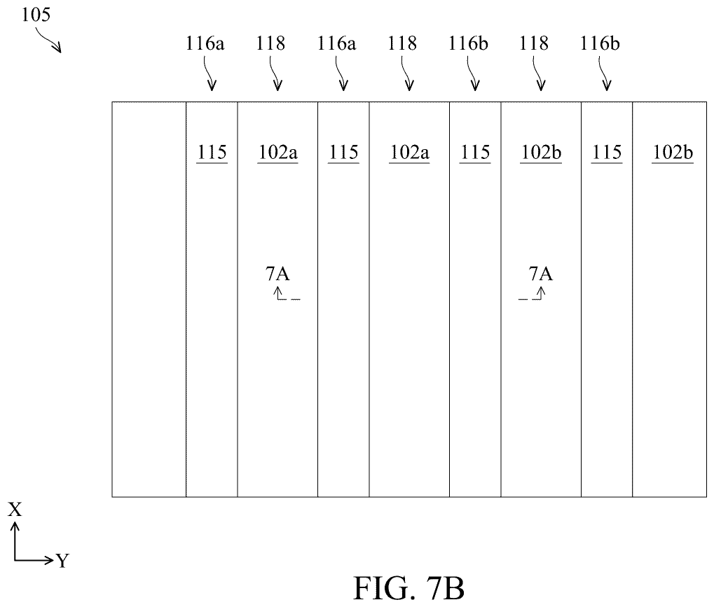

FIG. 7A is a cross-sectional view of the compound wafer 105, in accordance with some embodiments. FIG. 7B is a top view of the compound wafer 105 at the stage of processing shown in FIG. 7A. The view of FIG. 7A is taken along the cut lines 7A of FIG. 7B.

In FIGS. 7A and 7B, a plurality of fins 116a have been formed from the stack 107a, in accordance with some embodiments. A plurality of fins 116b have been formed from the stack 107b. The fins 116a/b can be formed in conjunction with a photolithography process. First, a hard mask layer 113 is formed on the stacks 107a/b. The hard mask layer 113 includes one or more of SiN, SiON, SiCN, SiOCN, SiOC, Al2O3, HfO2, ZrO2, SiC, or other suitable dielectric materials. A photoresist layer 114 is then formed on the hard mask layer 113. The photoresist layer 114 is patterned with the photolithography process. An etching process is then performed to pattern the hard mask layer 113 in the pattern of the fins 116a/b. An etching process is then performed to etch in the downward direction to form trenches 118 at the locations exposed by the mask. The fins 116a/b are formed by forming the trenches 118. The trenches 118a/b extend into the substrate 102a. Each fin 116a/b is an active region extending lengthwise in the X direction. As will be set forth in more detail below, a plurality of PFET devices will be formed in each fin/active region 116a. As will be set forth in more detail below, a plurality of NFET devices will be formed in each fin/active region 116b. The hard mask layer 113 corresponds to a gate protection hard mask layer, as will be set forth in more detail below.

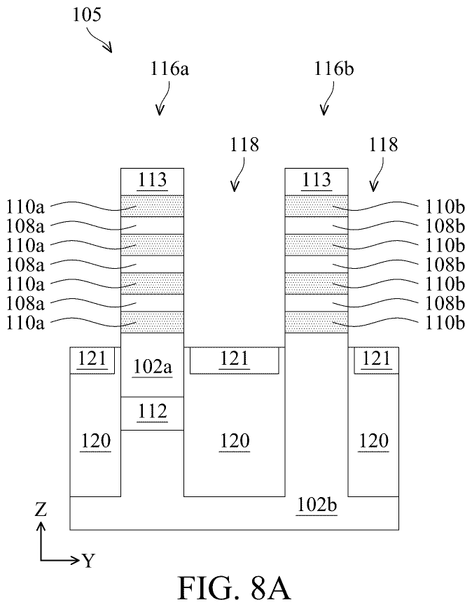

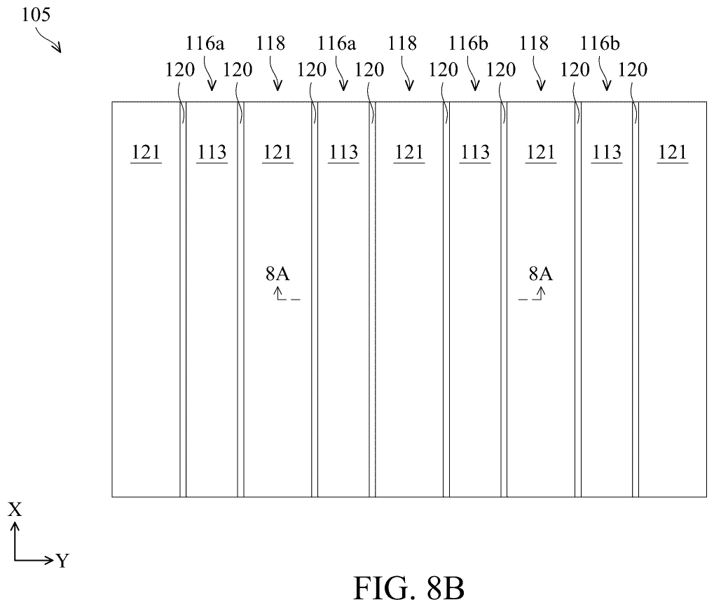

FIG. 8A is a cross-sectional view of the compound wafer 105, in accordance with some embodiments. FIG. 8B is a top view of the compound wafer 105 at the stage of processing shown in FIG. 8A. The view of FIG. 8A is taken along the cut lines 8A of FIG. 8B.

In FIGS. 8A and 8B, dielectric isolation structures 120 have been formed in recesses in the trenches 118, in accordance with some embodiments. Initially, the material of the dielectric isolation structures 120 may completely cover the fins 116a/b. Subsequently, an etchback process is performed to reduce the top surface of the dielectric isolation structures 120 to the level shown in FIG. 8A. The dielectric isolation structures 120 can include silicon oxide or another suitable dielectric material. In some embodiments, the dielectric isolation structures 120 correspond to shallow trench isolation regions. The dielectric isolation structures 120 extend lengthwise alongside and between the fins/active areas 116a/b.

A dielectric hard mask layer 121 has been formed on the dielectric isolation structures 120 in order to protect the dielectric isolation structures 120. The dielectric hard mask layer 121 includes a material that is different than the dielectric material of the dielectric isolation structures 120. The material of the dielectric hard mask layer 121 includes one or more of SiN, SiCN, SiOCN, SiOC, or other suitable dielectric materials.

The top view of FIG. 8B illustrates the fins 116a/b extending in the X direction with the hard mask layer 113 exposed, in accordance with some embodiments. The trenches 118 extend in the X direction between the fins 116, with the dielectric hard mask layer 121 and the portion of the dielectric isolation structures 120 exposed.

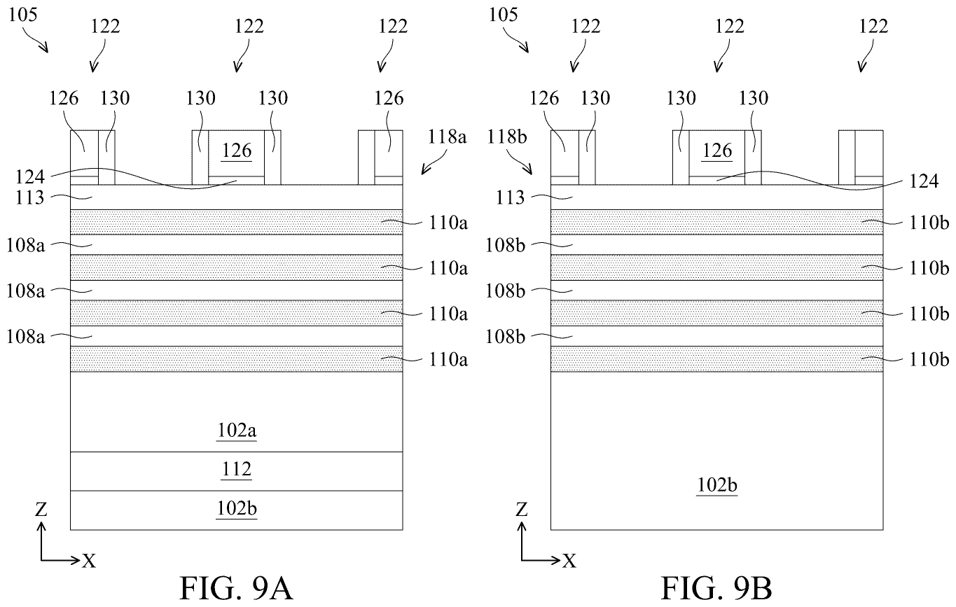

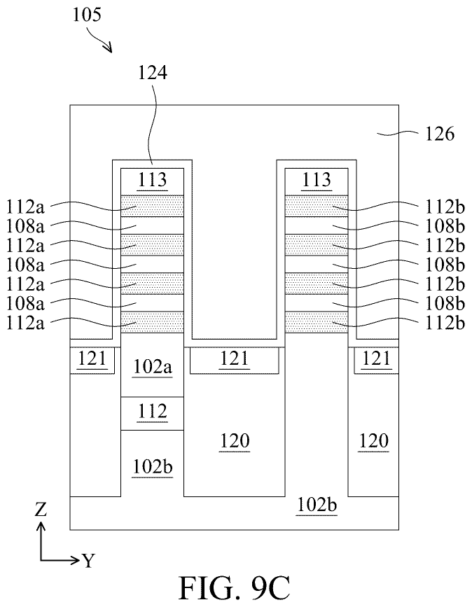

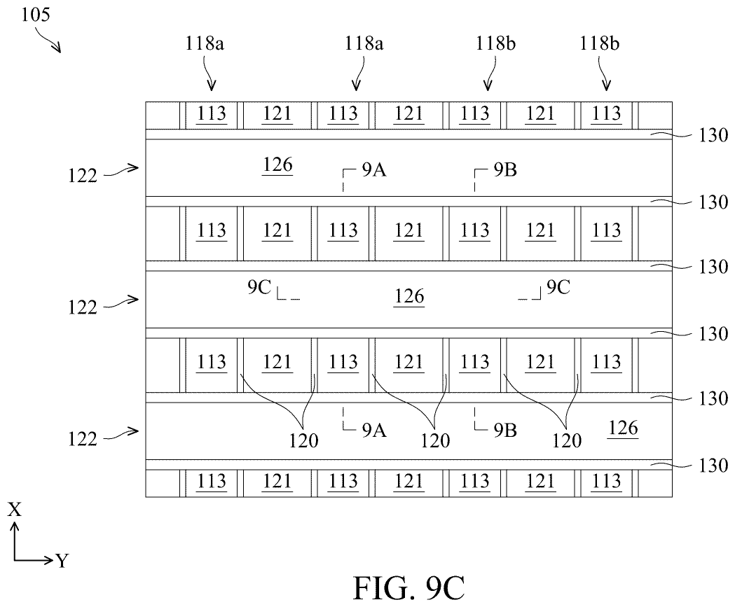

FIGS. 9A-9C are cross-sectional views of the compound wafer 105, in accordance with some embodiments. FIG. 9D is a top view of the compound wafer 105 at the stage of processing shown in FIGS. 9A-9C. The views of FIG. 9A-9C are taken along the cut lines 9A-9C, respectively, of FIG. 9D.

In FIGS. 9A-9D, a plurality of sacrificial gate structures 122 have been formed, in accordance with some embodiments. The sacrificial gate structures 122 extend in the Y direction across the trenches 118 and the fins 116a/b. The sacrificial gate structures 122 include a dielectric layer 124 and a sacrificial gate layer 126.

In some embodiments, the dielectric layer 124 includes one or more of SiO, SiN, SiON, SiCN, SiOCN, or other suitable dielectric materials. The dielectric layer 124 is formed by CVD, ALD, PVD, or other suitable deposition processes.

The sacrificial gate layer 126 can include materials that have a high etch selectivity with respect to the isolation structures 120. In an exemplary embodiment, the sacrificial gate layer 126 includes polysilicon. However, the sacrificial gate layer 126 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 126 may be deposited by physical vapor deposition (PVD), CVD, sputter deposition, or other techniques for depositing the selected material.

The sacrificial gate structure 122 is referred to as a sacrificial gate structure because the gate electrodes of the PFET and NFETs will be formed, in part, in place of the sacrificial gate layer 126. The sacrificial gate structure 122 may also include one or more additional dielectric layers above the sacrificial gate layer 126. Various configurations and materials can be utilized for the sacrificial gate structure 122 without departing from the scope of the present disclosure.

In FIGS. 9A-9D, a gate spacer layer 130 has been formed on sidewalls of the sacrificial gate layer 126. In one example, the gate spacer layer 130 includes silicon nitride. Alternatively, the gate spacer layer 130 can include silicon oxide, silicon oxynitride, silicon carbonitride, silicon oxycarbonitride, fluorine-doped silicate glass (FSG), or another suitable dielectric material. The gate spacer layer 130 may include multiple dielectric layers. The gate spacer layer 130 may also be termed a sidewall spacer.

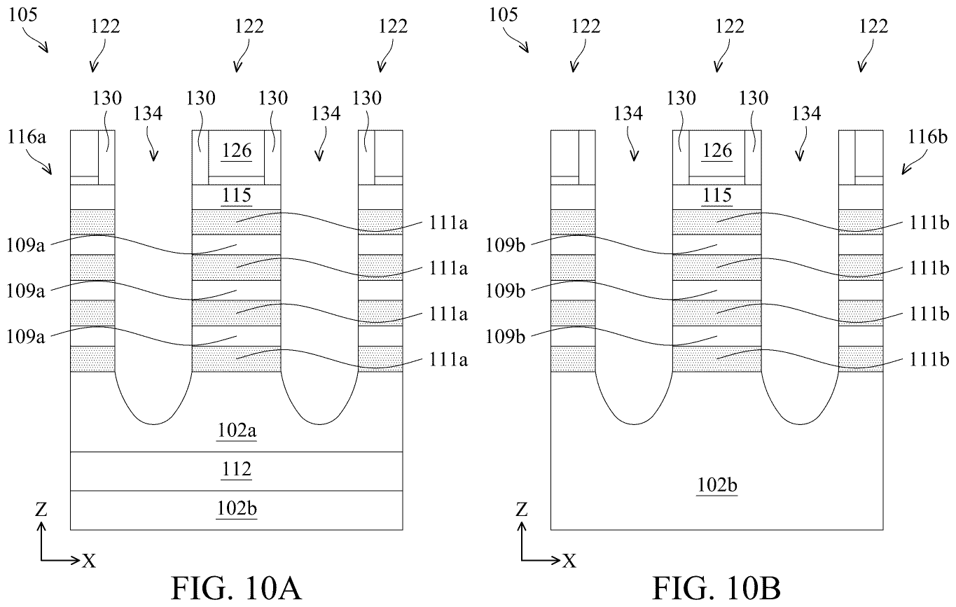

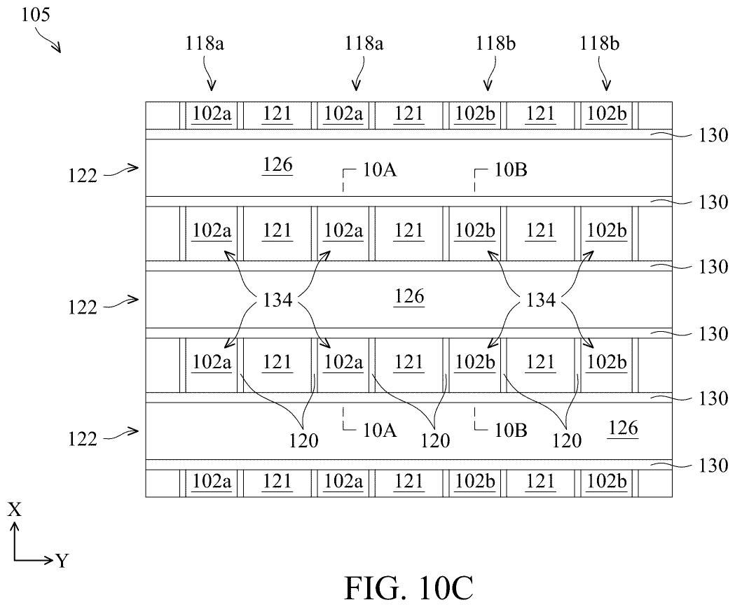

FIGS. 10A and 10B are cross-sectional views of the wafer 105, in accordance with some embodiments. FIG. 10C is a cross-sectional view of the wafer 105 at the same stage of processing of FIGS. 10A and 10B. The cross-sectional views of FIGS. 10A and 10B are taken along cut lines 10A and 10B, respectively, of FIG. 10C.

In FIGS. 10A-10C, an etching process has been performed to form source/drain trenches 134 in the fins 116a/b. In particular, the etching process removes the portions of the sacrificial semiconductor layers 110a/b and semiconductor layers 108a/b that are not directly below the gate spacer layer 130. The etching process can include an anisotropic etch that selectively etches in the downward (z-)direction. The source/drain trenches 134 extend into the substrate 102a at the fin 116a. The source/drain trenches 134 extend into the substrate 102b at the fin 116b.

Formation of the source/drain trenches 134 in the fin 116a results in formation of a plurality of stacks of channels 109a from the semiconductor layers 108a and sacrificial semiconductor nanostructures 111a from the sacrificial semiconductor layers 110a. Formation of the source/drain trenches 134 in the fin 116b results in formation of stacks of channels 109b from the semiconductor layers 108b and sacrificial semiconductor nanostructures 111b from the sacrificial semiconductor layers 110b. The channels 109a will be channels of GAA PFET devices, as will be set forth in more detail below. The channels 109b will be channels of GAA NFET devices, as will be set forth in more detail below. The sacrificial semiconductor nanostructures 111a/b will eventually be replaced with gate metals of the PFET and NFET devices. Formation of the trenches 134 also results in dielectric structures 115 from the hard mask layer 113. The dielectric structures 115 have substantially the same lateral (X-Y) dimensions as the channels 109a/b at the stage of processing shown in FIGS. 10A-10C.

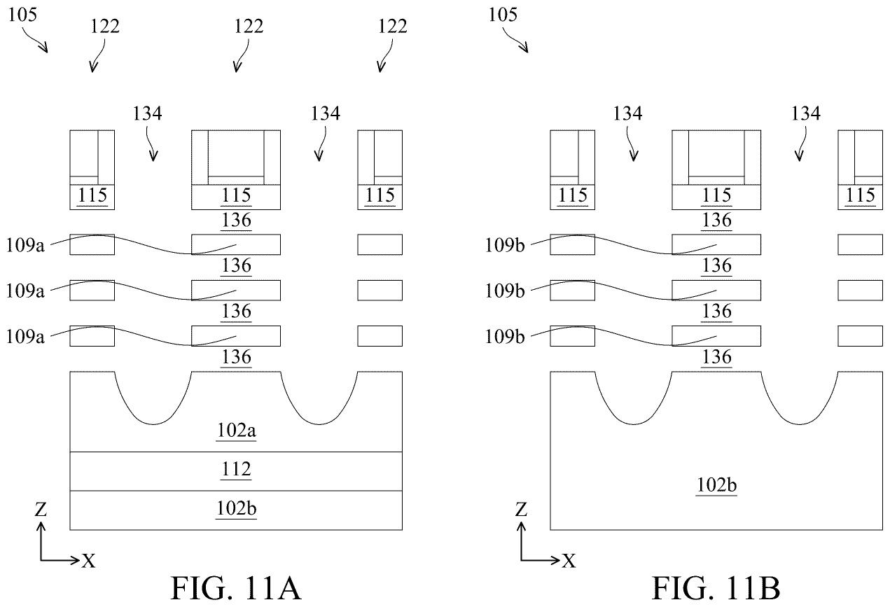

FIGS. 11A and 11B are cross-sectional views of the wafer 105, in accordance with some embodiments. In FIGS. 11A and 11B, an etching process has been performed. The etching process selectively etches the material of the sacrificial semiconductor nanostructures 111a/b with respect to the materials of other exposed structures, including the channels 109a/b. The result of the etching process is that the sacrificial semiconductor nanostructures 111a/b have been completely removed. This leaves gaps 136 between the channels 109a/b.

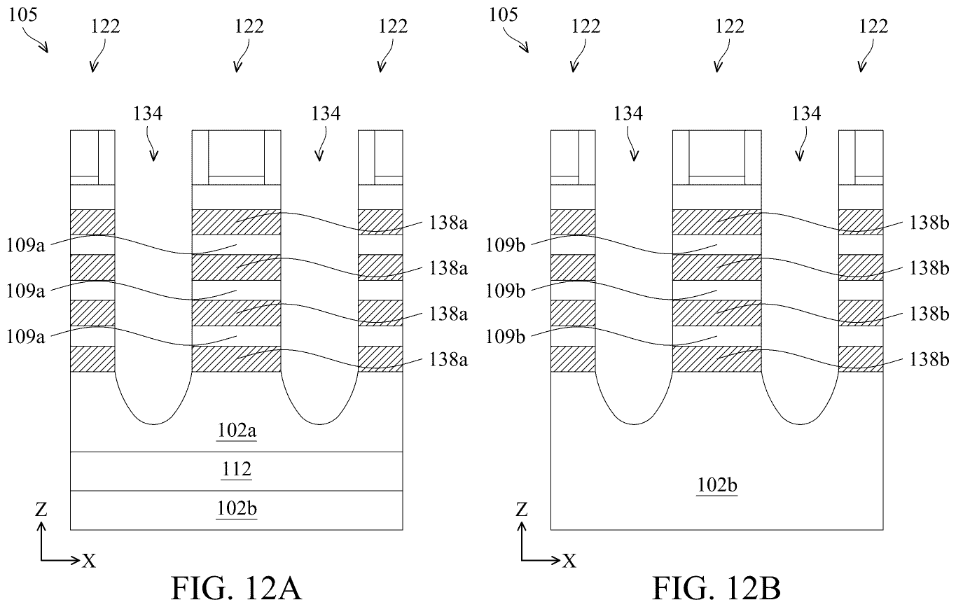

FIGS. 12A and 12B are cross-sectional views of the wafer 105, in accordance with some embodiments. In FIGS. 12A and 12B, sacrificial dielectric nanostructures 138a/b have been formed in place of the gaps 136. Accordingly, sacrificial dielectric nanostructures 138a/b are formed in place of the sacrificial semiconductor nanostructures 111a/b. As will be set forth in more detail below, the sacrificial dielectric nanostructures 138a/b will eventually be removed and gate metals will be formed in their place.

The sacrificial dielectric nanostructures 138a/b are formed by conformally depositing a dielectric layer in the source/drain trenches 134. The conformal deposition results in dielectric material filling the gaps 136. The deposition process can include CVD, ALD, PVD, or other suitable deposition processes. The dielectric layer can include SiO, SiN, SiOCN, SiOC, SiCN, or other suitable dielectric materials. In one example, the dielectric layer includes silicon oxide. After deposition of the dielectric layer, an anisotropic etching process is performed that etches the dielectric layer in the downward direction. Portions of the dielectric layer exposed in the trenches 134 are removed. The portions of the dielectric layer protected in the gaps 136 remain. The result is that the sacrificial dielectric nanostructures 138a/b are formed as shown in FIGS. 12A and 12B. The sacrificial dielectric nanostructures 138a/b may also be termed dielectric interposers. In some embodiments, the material of the sacrificial dielectric nanostructures 138 is different than the material of the hard mask layer 113. In some embodiments, the sacrificial dielectric nanostructures 138 are selectively etchable with respect to the material of the hard mask layer 113.

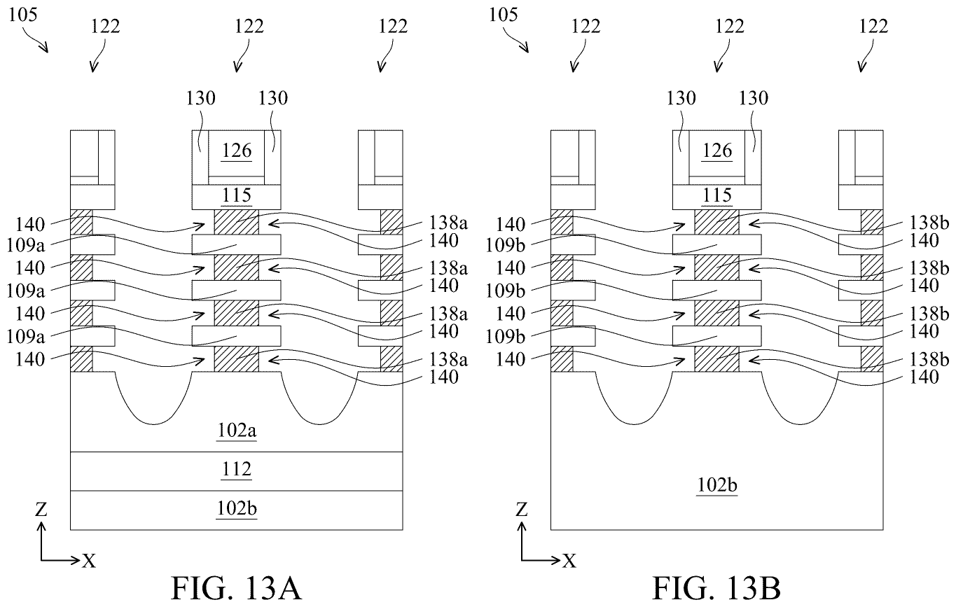

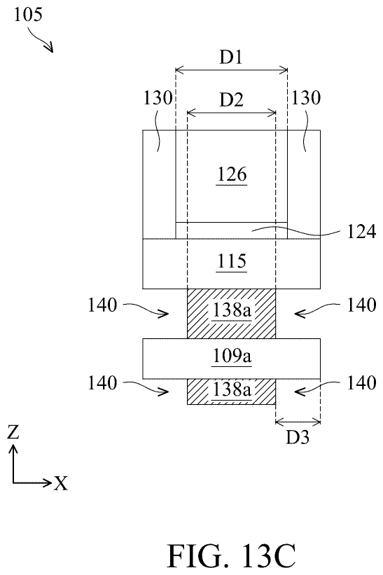

FIGS. 13A and 13B are cross-sectional views of the wafer 105, in accordance with some embodiments. In FIGS. 13A and 13B, an isotropic etching process is performed to form recesses 140 in the sacrificial dielectric nanostructures 138a/b. The isotropic etching process selectively etches the material of the sacrificial dielectric nanostructures 138a/b with respect to the channels 109a/b. The isotropic etching process is a timed process that recesses the sacrificial dielectric nanostructures 138a/b without entirely removing the sacrificial dielectric nanostructures 138a/b.

As can be seen in FIGS. 13A and 13B, the sacrificial gate layer 126 is wider in the X direction than are the remaining portions of the sacrificial dielectric nanostructures 138a/b. As will be set forth in more detail below, the width of the sacrificial gate layer 126 in the X direction correlates to an outer gate length, as the sacrificial gate layer 126 will eventually be replaced by a gate metal. The width of the sacrificial dielectric nanostructures 138a/b correlates with an inner gate length, as the sacrificial dielectric nanostructures 138a/b will eventually be replaced by a gate metal. The recessing step is selected to form recesses 140 with a depth in the X direction that results in the sacrificial dielectric nanostructures 138a/b having a width in the X direction that is less than the width of the sacrificial gate layer 126 in the X direction. In some embodiments, the depth of the recesses 140 is larger than a thickness in the X direction of the gate spacer layer 130. This allows for forming the sacrificial dielectric nanostructures 138a/b narrower in the X direction than the sacrificial gate layer 126.

FIG. 13C is an enlarged cross-sectional view of a portion of the wafer 105 at the fin 116a at the same stage of processing of FIGS. 13A and 13B. FIG. 13C illustrates that the sacrificial gate layer 126 has a width dimension D1 in the X direction and that the sacrificial dielectric nanostructures 138a/b have a width dimension D2 in the X direction after formation of the recesses 140. The dimension D2 is less than the dimension D1. As will be set forth in more detail below, this helps contribute to the transistors having inner gate lengths that are shorter than the outer gate lengths.

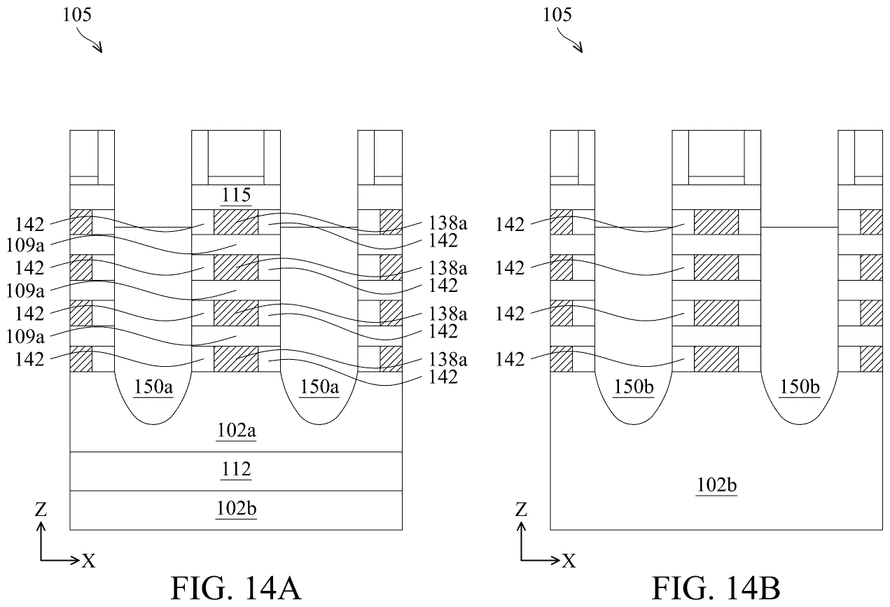

FIGS. 14A and 14B are cross-sectional views of the wafer 105, in accordance with some embodiments. In FIGS. 14A and 14B, inner spacers 142 have been formed in the recesses 140 of the sacrificial dielectric nanostructures 138a/b. The inner spacers 142 can be formed by depositing a dielectric layer on the exposed sidewalls of the channels 109a/b, on sidewalls of the gate spacers 130, and in the recesses 140 formed in the sacrificial dielectric nanostructures 138a/b. The dielectric layer can include silicon oxide, silicon nitride, silicon oxynitride, silicon carbonitride, silicon oxycarbonitride, FSG, a low-K dielectric material or other dielectric materials without departing from the scope of the present disclosure. The dielectric layer can be formed by CVD, PVD, ALD, or via another process. The lateral thickness (in the x-direction) of the dielectric layer may be between 2 nm and 10 nm. Other thicknesses, materials, and deposition processes can be utilized for the dielectric layer without departing from the scope of the present disclosure.

An etching process is then performed to remove portions of the dielectric layer that are not vertically below a channel 109a/b or the dielectric structure 113. The etching process defines the inner spacers 142 as shown in FIGS. 14A and 14B. Other processes can be utilized to form the inner spacers 142 without departing from the scope of the present disclosure.

In FIG. 14A source/drain regions 150a have been formed in the source/drain trenches 134, in accordance with some embodiments. The source/drain regions 150a may be formed in an epitaxial growth process from the channels 109a and the substrate 102a. The source/drain regions 150a include a semiconductor material. The semiconductor material can include a same semiconductor material as the channels 109a. Alternatively, the semiconductor material of the source/drain regions 150a can be different than the semiconductor material of the channels 109a. The source/drain regions 109a may be doped in situ with dopant atoms during the epitaxial growth process. In the example in which the lower transistor is a P-type transistor, the source/drain regions 150a may be doped in situ with P-type dopant atoms. The P-type dopant atoms can include boron or other P-type dopant atoms.

In FIG. 14B, source/drain regions 150b have been formed, in accordance with some embodiments. The source/drain regions 150b may be formed in an epitaxial growth process from the channels 109b. The source/drain regions 150b include a semiconductor material. The semiconductor material can include a same semiconductor material as the channels 109b. Alternatively, the semiconductor material of the source/drain regions 150b can be different than the semiconductor material of the channels 109b. The source/drain regions 150b may be doped in situ with dopant atoms during the epitaxial growth process. In an example in which the upper transistor is an N-type transistor, the source/drain regions 150b may be doped in situ with N-type dopant atoms. The dopant atoms can include phosphorus, arsenic, or other N-type dopant atoms.

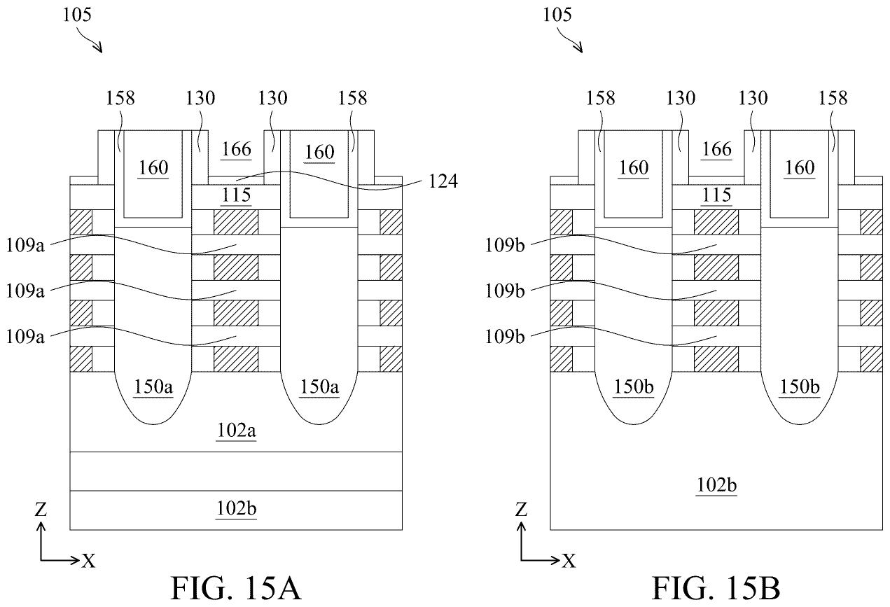

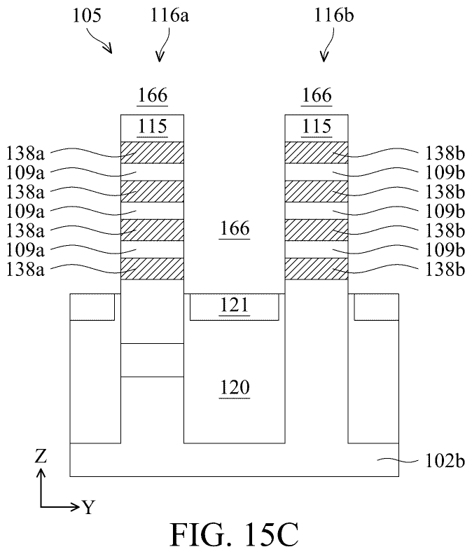

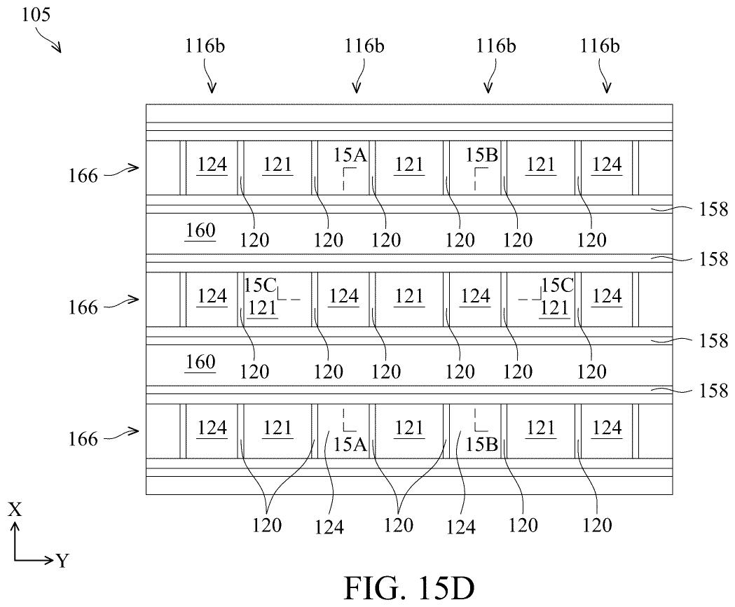

FIGS. 15A-15C are cross-sectional views of the compound wafer 105, in accordance with some embodiments. FIG. 15D is a top view of the compound wafer 105 at the stage of processing shown in FIGS. 15A-15C. The views of FIG. 15A-15C are taken along the cut lines 15A-15C, respectively, of FIG. 15D.

In FIGS. 15A-15D, a contact etch stop layer (CESL) 158 has been deposited on the top surfaces of the source/drain regions 150a/b and on side surfaces of the uppermost inner spacers 142, the dielectric structures 115, and the gate spacer layers 130. The CESL 158 is initially conformally deposited on all exposed surfaces. The CESL 158 is deposited by CVD, ALD, PVD, or another suitable deposition process. The CESL 158 includes one or more of SiN, SiON, SiOCN, SiCN, or other suitable dielectric materials.

In FIGS. 15A-15D, an interlevel dielectric layer 160 has been deposited. The interlevel dielectric layer 160 is deposited on the CESL 158. The interlevel dielectric layer 160 is deposited by CVD, ALD, PVD, or another suitable deposition process. The interlevel dielectric layer 158 includes one or more of SiO, SiN, SiON, SiOCN, SiCN, FSG, or other suitable dielectric materials.

In FIGS. 15A-15D, a CMP process has been performed. The CMP process planarizes the top surfaces of the CESL 158, the interlevel dielectric layer 160, the gate spacer layers 130, and the sacrificial gate structures 126.

In 15A-15D, the sacrificial gate layer 126 has been removed, in accordance with some embodiments. The sacrificial gate layer 126 can be removed by an etching process that selectively etches the material of the sacrificial gate layer 126 with respect to adjacent materials, such as the gate spacer layers 130. Removal of the sacrificial gate layer 126 results in gate trenches 166 between the gate spacer layers 130.

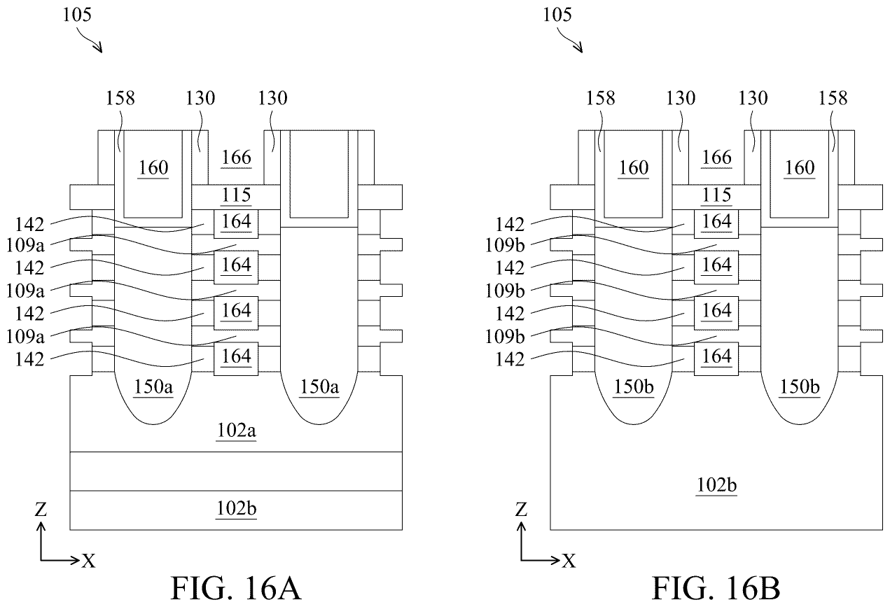

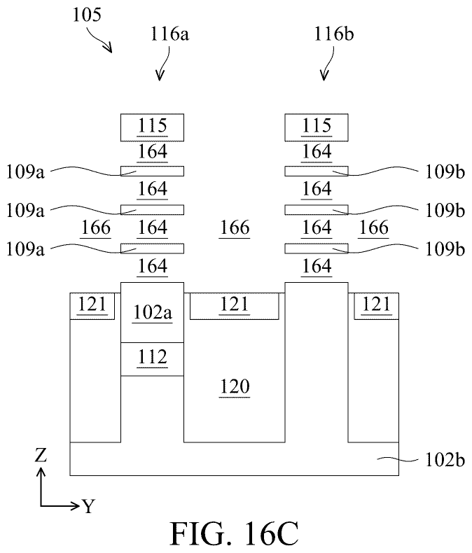

FIGS. 16A-16C are cross-sectional views of the compound wafer 105, in accordance with some embodiments. FIG. 16D is a top view of the compound wafer 105 at the stage of processing shown in FIGS. 16A-16C. The views of FIG. 16A-16C are taken along the cut lines 16A-16C, respectively, of FIG. 16D.

In FIGS. 16A-16D, an etching process has been performed to remove the sacrificial dielectric nanostructures 138a/b, in accordance with some embodiments. The sacrificial dielectric nanostructures 138a/b can be removed by a selective etching process using an etchant that is selective to the material of the channels 109a/b, such that the sacrificial dielectric nanostructures 138a/b are removed without substantially etching the channels 109a/b and the inner spacers 142. In some embodiments, the etching process is an isotropic etching process using an etching gas, and optionally, a carrier gas, where the etching gas comprises F₂ and HF, and the carrier gas may be an inert gas such as Ar, He, N₂, combinations thereof, or the like. In some embodiments, the etching process results in a rounding of side surfaces of the channels 109a/b. The etching process also results in gaps 164 between the channels 109a/b. The gaps 164 are contiguous with the gate trenches 166.

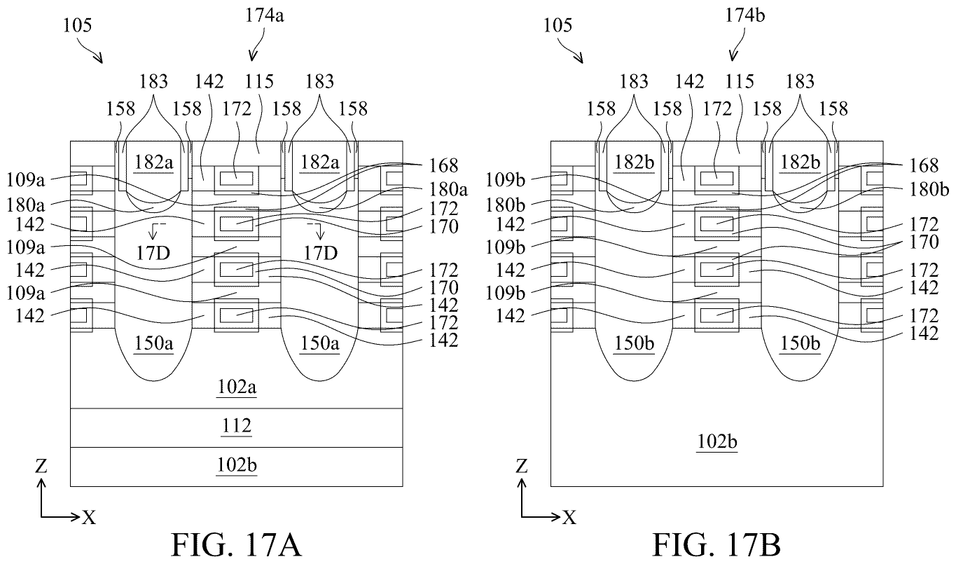

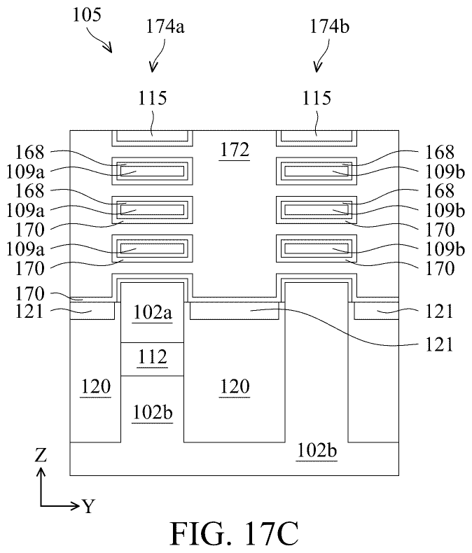

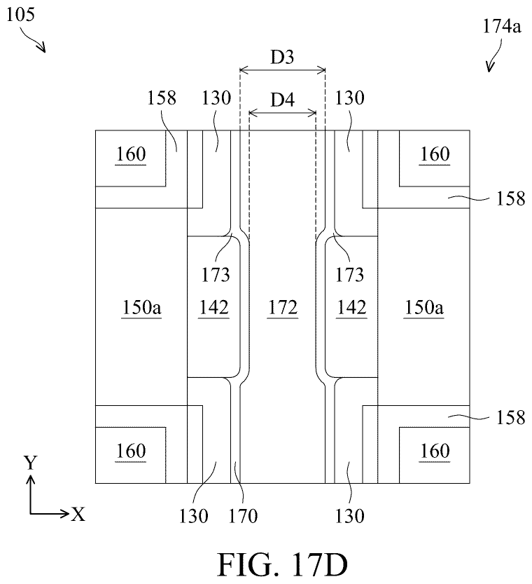

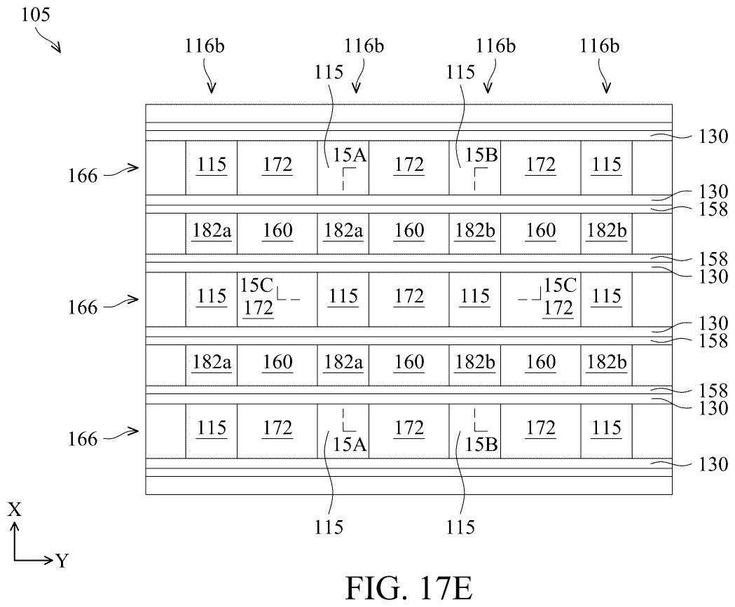

FIGS. 17A-17C are cross-sectional views of the compound wafer 105, in accordance with some embodiments. FIG. 17D is an enlarged cross-sectional view of the wafer 105 taken along cut lines 17D from FIG. 17A, in accordance with some embodiments. FIG. 17E is a top view of the compound wafer 105. FIGS. 17A-17C are taken along cut lines 17A-17C, respectively, from FIG. 17E.

In FIGS. 17A-17E, a gate dielectric has been formed, in accordance with some embodiments. The gate dielectric includes an interfacial gate dielectric layer 168 and a high-K gate dielectric layer 170. The interfacial gate dielectric layer 168 has been deposited on exposed portions of the channels 109a/b, in accordance with some embodiments. The interfacial gate dielectric layer 168 forms directly on the exposed portions of the channels 109a/b. The high-K gate dielectric layer 170 forms on the interfacial gate dielectric layer 168 and on other exposed surfaces, such as the exposed sidewalls of the gate spacer layer 130, and the inner spacers 148.

The interfacial gate dielectric layer 168 is wrapped around the channels 109a/b. The interfacial gate dielectric layer 168 can include a dielectric material such as silicon oxide, silicon nitride, or other suitable dielectric materials. The interfacial gate dielectric layer 168 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 168 can be formed by a thermal oxidation process, a chemical vapor deposition (CVD) process, or an atomic layer deposition (ALD) process. The interfacial gate dielectric layer 168 can have a thickness between 0.5 nm and 2 nm. Other materials, deposition processes, and thicknesses can be utilized for the interfacial gate dielectric layer 168 without departing from the scope of the present disclosure.

The high-K gate dielectric layer 170 is deposited in a conformal deposition process. The conformal deposition process deposits the high-K gate dielectric layer 170 on the interfacial gate dielectric layer 168, on the substrate 102a, on the middle isolation structure 113, on the dielectric isolation structure 120, and on the gate spacer layer 130. The high-K gate dielectric layer 170 is wrapped around the channels 109a/b. The high-K gate dielectric layer 170 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂-Al₂O₃) alloy, other suitable high-K dielectric materials, and/or combinations thereof. The high-K gate dielectric layer 170 may be formed by CVD, ALD, or any suitable method. Other thicknesses, deposition processes, and materials can be utilized for the high-K gate dielectric layer 170 without departing from the scope of the present disclosure.

In FIGS. 17A-17E, a gate metal 172 has been deposited, in accordance with some embodiments. The gate metal 172 is deposited in place of the sacrificial gate layer 126 and the sacrificial dielectric nanostructures 138a/b. Accordingly, the gate metal 172 is positioned in the gate trench above each stack of channels 109a/b. The gate metal 172 is also wrapped around the channels 109a/b of each stack.

In FIGS. 17A-17E, a single gate metal 172 is illustrated as a gate electrode of the transistors 101. However, in practice, the gate metal 172 can include multiple gate metals. For example, the gate metal 172 can include one or more liner layers, one or more work function layers, and a gate fill material that fills the remaining spaces between the gate spacer layers 130. The gate metal 172 can include one or more of Ti, TiN, Ta, TaN, Al, Cu, Co, Ru, W, Au, or other suitable conductive materials. The gate metal 172 can be deposited by PVD, ALD, or CVD. The gate metal 172 may also be termed a gate electrode.

As set forth in further detail below in relation to FIG. 17D, the gate metal 172 has an inner gate length corresponding to the length of the gate metal 172 in the X direction in the gaps 166 between and around the channels 109a/b. The gate metal 172 has an outer gate length corresponding to the length of the gate metal 172 in the gate trench 166 extending in the Y direction from the sides of the channels 109a/b in the Y direction, as can be seen in FIG. 17E. The outer gate length has a dimension D3 in the X direction. The inner gate length has a dimension D4 in the X direction. In some embodiments, D3 is between 5.5 nm and 18 nm, though other dimensions can be utilized without departing from the scope of the present disclosure. D4 is between 5 nm and 13 nm, though other dimensions can be utilized without departing from the scope of the present disclosure. D4 is smaller than D3 by between 0.5 nm and 5 nm.

Embodiments of the present disclosure enable generation of gate electrodes having inner gate lengths less than 13 nm. It is challenging to make sacrificial gate layers having a width in the X direction less than 15 nm due to a tendency to collapse. However, by utilizing the principles disclosed herein, inner gate length in less than 13 nm can be achieved without forming sacrificial gate layers with such small dimensions.

After formation of the gate metal 172, a CMP process is performed. The CMP process removes excess material of the gate metal 172 from the dielectric structures 115. The result is that the top surfaces of the gate metal 172, hard mask structures 172, and the CESL 158 are coplanar. The thickness of the dielectric structures 115 may be reduced during the CMP process. In some embodiments, the hard nanostructures 115 have a thickness between 1 nm and 15 nm.

In FIGS. 17A-17E, processing of the transistors 174a and the transistors 174b are substantially complete. The transistor 174a includes channels 109a extending in the X direction between source/drain regions 150a. The portion of the gate metal 172 wrapped around the channels 109a corresponds to a gate electrode of the transistor 174a. When the transistor 174a is on and current is flowing, the direction of the current is in the X direction between the channels 150a. In the example in which the transistor 174a is a PFET and the channels 109a are silicon, the crystal orientation of the channels 109a is 110. This provides improved mobility of holes traveling in the X direction. This further enables the vertical thickness of the channels 109a to be relatively small without suffering performance penalties. In some embodiments, the vertical thickness of the channels 109a is between 0.5 nm and 8 nm, though other thicknesses can be utilized. Other materials, thicknesses, and crystal orientations can be utilized without departing from the scope of the present disclosure.

The transistor 174b includes channels 109b extending in the X direction between source/drain regions 150b. The portion of the gate metal 172 wrapped around the channels 109b corresponds to a gate electrode of the transistor 174b. When the transistor 174b is on and current is flowing, the direction of the current is in the X direction between the channels 150b. In the example in which the transistor 174b is an NFET and the channels 109b are silicon, the crystal orientation of the channels 109b is 100. This provides improved mobility of electrons traveling in the X direction. This further enables the vertical thickness of the channels 109b to be relatively small without suffering performance penalties. In some embodiments, the vertical thickness of the channels 109b is between 0.5 nm and 8 nm. Other materials, thicknesses, and crystal orientations can be utilized without departing from the scope of the present disclosure.

In FIGS. 17A-17E, a photolithography and corresponding etching process have been performed to etch portions of the dielectric layers 160 and 158 to expose the source/drain regions 150a/b of the transistors 174a/b. A silicide 180a/b has been formed on the exposed top surfaces of the source/drain regions 150a/b. The silicide 180a/b can include titanium silicide, nickel silicide, or other types of silicide. After formation of the silicide 180a/b, source/drain contacts 182a/b are formed in contact with the silicide 180a/b. The source/drain contacts 182a/b can include one or more of W, Ta, Ti, Ru, Co, TiN, TaN, WN, or other suitable conductive materials. A CMP process has been performed to remove excess material of the source/drain contacts 182a/b. The source/drain contacts 182a/b enable voltages to be applied to the source/drain regions 150a/b.

In some embodiments, a liner layer 183 is formed on the sides of the remaining portion of the CESL layer 158 prior to formation of the source/drain contacts 182a/b. The liner layer 183 can be a dielectric layer or a conductive layer. In some embodiments, the liner layer 183 includes SiN, though other dielectric materials can be utilized without departing from the scope of the present disclosure.

Though not shown in FIGS. 17A-17D, after formation of the source/drain contacts 182b, a stack of dielectric layers is formed over the transistors 174a/b. A plurality of metal lines and conductive vias are formed in the stack of dielectric layers to enable the provision of signals to and from the transistors 174a/b.

The wafer 105 will eventually be diced into a plurality of integrated circuits. Each integrated circuit includes a plurality of transistors 174a/b.

In some embodiment, the shorter inner gate length can increase driving current and reduce channel capacitance (induced by metal gate and channel). This results in improved switching speeds and overall device performance. By scaling down the inner gate length only while keeping the outer gate length unchanged, the process window can be improved, so that the challenges associated with the gate replacement process, such as Vt tuning via work function material and the use of multiple metal gates, are minimized. That is, since the outer gates are larger than the inner gates, the spaces between channels (where inner gates to be formed) can be filled well before the gate fill material merging at the upper portions (where outer gates to be formed), so as to avoid generating seams or voids in the inner gates.

In some embodiments, the top channel 109b has an asymmetric gate length because its topside is in contact with the outer gate (longer gate length D3), while its bottom-side is in contact with the inner gate (shorter gate length D4).

Furthermore, by providing different wafer crystal lattice orientations or materials for NFETs and PFETs, the mobility can be kept or the mobility degradation induced by the thin channel height can be reduced.

In FIG. 17D, spurs 173 are formed of the high-k gate dielectric layer 170 adjacent to the inner spacers 142 and the gate spacer layers 130. The spurs 173 result, in part, from the fact that the recesses 140 in which the inner spacers 142 are formed extend further in more than the inner walls of the gate spacer layer 130. The spurs 173 are pointed protrusions that extend in the X direction into creases between the inner spacers 142 and the gate spacer layers 130. The enlarged view of FIG. 17D also illustrates a second gate spacer layer 131 between the gate spacer layer 130 and the CESL 158, in accordance with some embodiments. Accordingly, in some embodiments, the gate spacer layer is a dual gate spacer layer including the gate spacer layer 130 and the gate spacer layer 131. In some embodiments, the gate spacer layer 131 includes a material selected from SiOCN, SiCN, SiON, or other suitable dielectric materials.

The wafer 105 will eventually be diced into a plurality of integrated circuits. Each integrated circuit includes a plurality of transistors 174a/b.

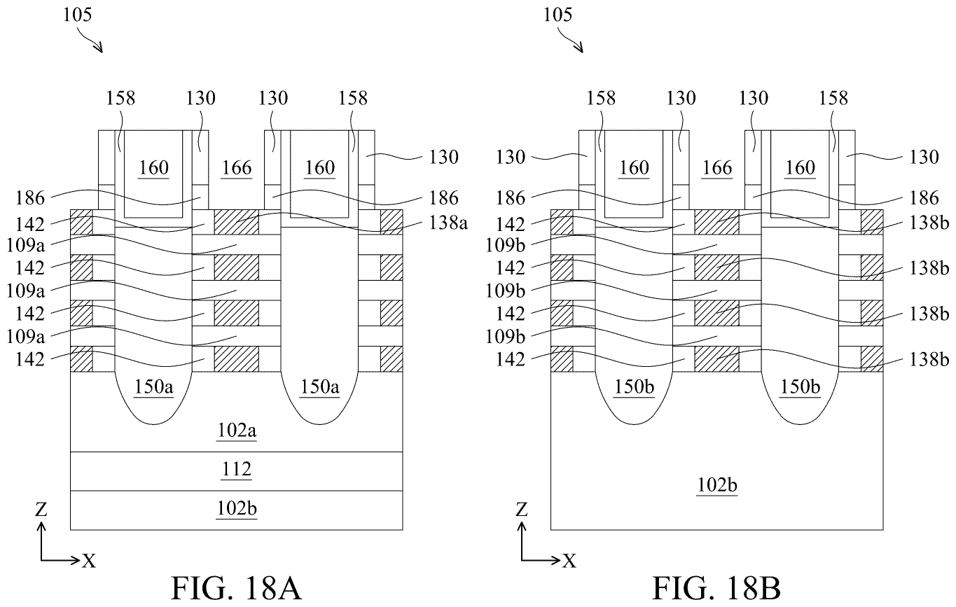

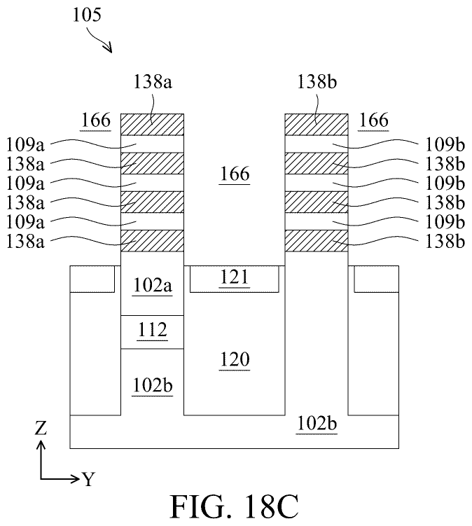

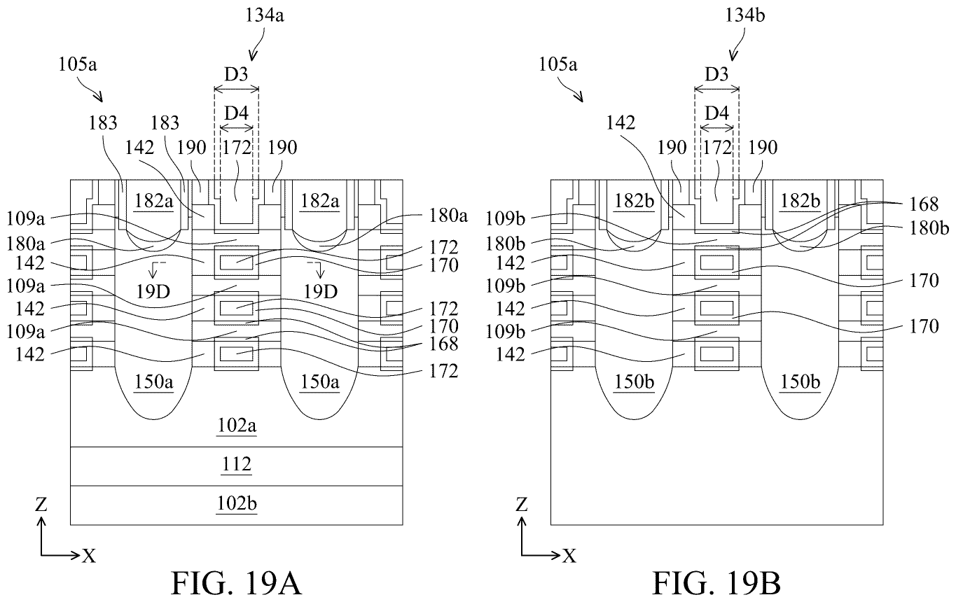

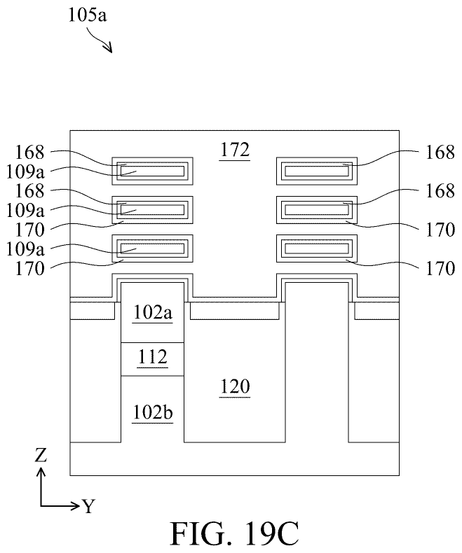

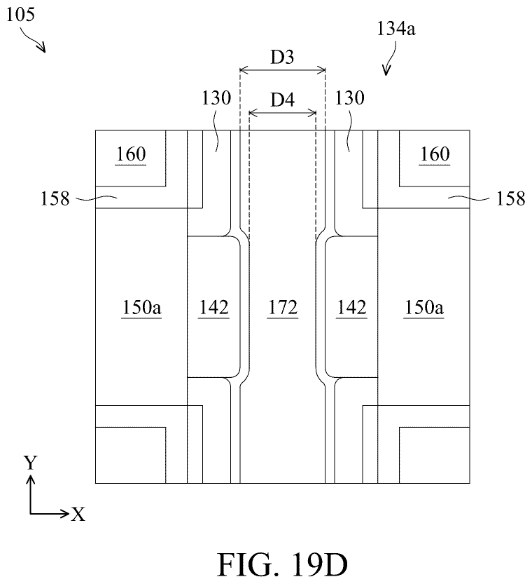

FIGS. 18A-19D are cross-sectional views a wafer 105 at intermediate stages of processing, in accordance with some embodiments.

FIGS. 18A-18C are cross-sectional views of the wafer 105 at a stage of processing, corresponding to the stage of processing shown in FIGS. 15A-15D, except that in FIGS. 18A-18C, an etching process has been performed, in accordance with some embodiments. The etching process removes the dielectric layer 124 and a central portion of each dielectric structure 115 not covered by the gate spacer layer 130, in accordance with some embodiments. The etching process is an anisotropic etching process that etches in the downward direction and selectively etches the material of the dielectric structure 115 with respect to other exposed materials. After the etching process, hard mask remnants 186 are present on top of the highest inner spacers 142. A portion of the top surface of the highest inner spacers 142 is also exposed.

In FIGS. 19A-19D, the sacrificial semiconductor nanostructures 111a/b have been removed, the interfacial gate dielectric layer 168 has been formed, the high-K gate dielectric layer 170 has been formed, and the gate metal 172 has been formed substantially as described in relation to FIGS. 17A-17D. FIGS. 19A and 19B illustrate the T-shape of the gate metal 172 above highest channel 109b. In particular, the upper part of the gate metal 172 includes a first portion above the highest channels 109b with the shorter gate length dimension D4 and a second portion above the first portion with the longer gate length dimension D3. The hard mask remnants 186 are present on the highest inner spacers 142. A CMP process has been performed to make the top surface of the gate metal 172 coplanar with the top surface of the hard mask remnants 186. The view of FIG. 19D is substantially identical to the view of FIG. 17D. In some embodiments, the hard mask remnants 186 have a smaller width than the inner spacers 142, as, in some embodiments, the hard mask remnants 186 are self aligned with the gate layers 130.

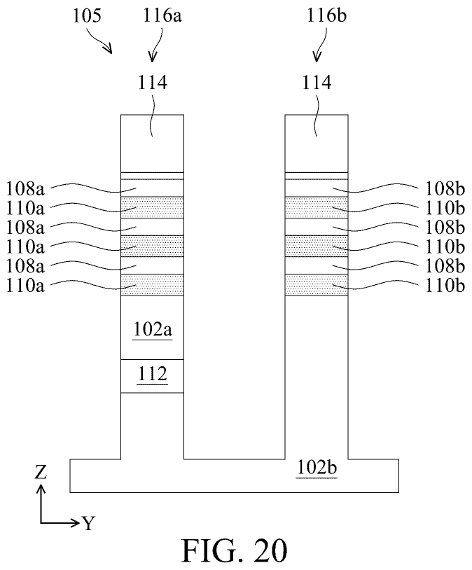

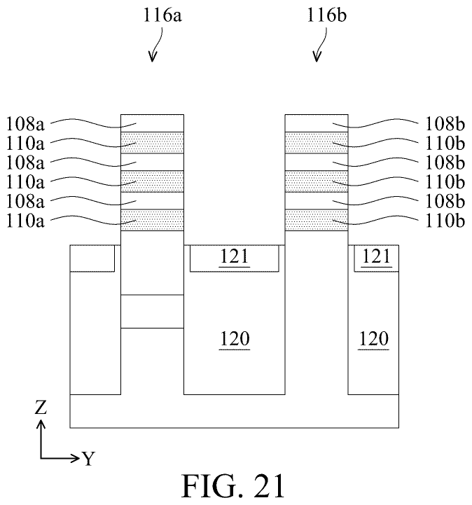

FIGS. 20-22D are cross-sectional views of a wafer 105, in accordance with some embodiments. At the stage of processing shown in FIG. 20, the wafer 105 is substantially identical to the stage of processing shown in FIG. 7A, except that the hard mask layer 113 has not been formed. A dielectric layer 191 has been formed between the top semiconductor layers 108a/b and the photoresist layer 114. In some embodiments, the dielectric layer 191 includes silicon dioxide, though other materials can be utilized without departing from the scope of the present disclosure. Furthermore, the top sacrificial semiconductor layer 111a/b of FIG. 7A is not present in FIG. 21. Instead, the top semiconductor layer 109a/b is higher than the highest sacrificial semiconductor layer 111a/b.

In FIG. 21, the dielectric isolation structures 120 and the hard mask layer 121 have been formed, substantially as described in relation to FIG. 8A.

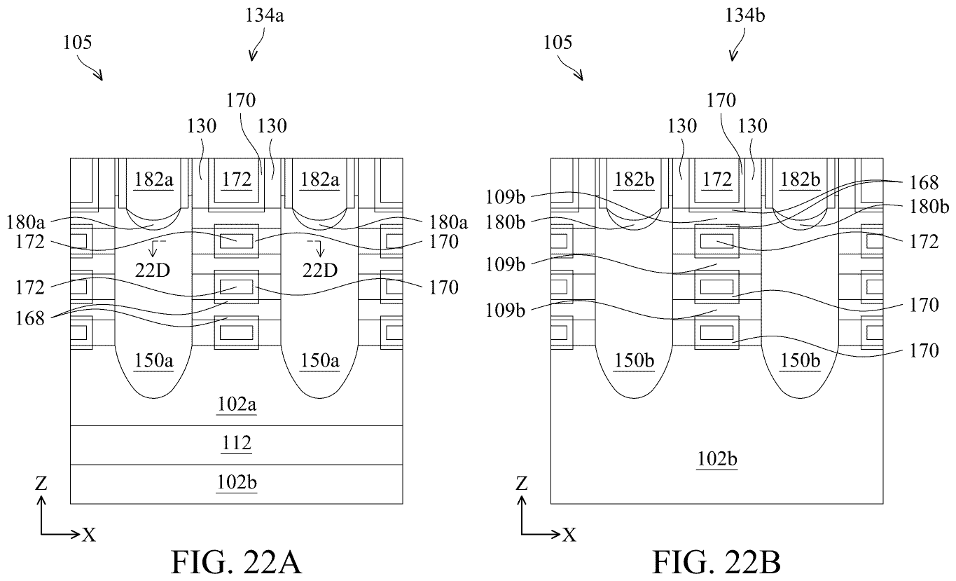

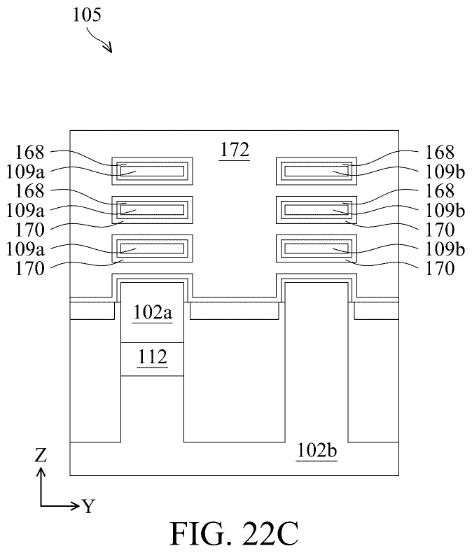

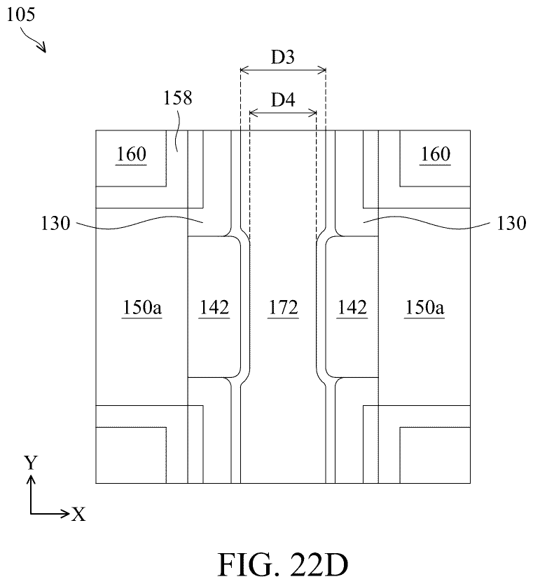

In FIGS. 22A-22D, the transistors 134a/134b have been formed substantially as described in relation to FIGS. 9A-17E, except that the dielectric structures are not present. The portion of the gate metal 172 above the highest channels 109a/b has the larger outer gate length dimension D3, portion of the gate metal wrapped around the channels 109a/b has the smaller inner gate length dimension D4. The view of FIG. 22D is substantially identical to the view of FIG. 17D.

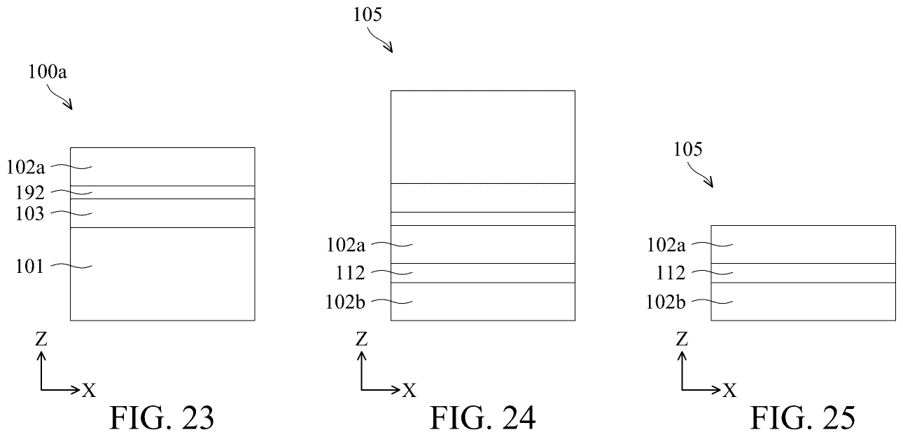

FIGS. 23-30D are cross-sectional views of a wafer 105 at various stages of processing, in accordance with some embodiments.

FIG. 23 illustrates a wafer 100a, in accordance with some embodiments. The wafer 100a of FIG. 23 includes the semiconductor layers 101 and 103 substantially as described in relation to FIG. 1A. The wafer 100a of FIG. 23 includes a further semiconductor layer 192 between the semiconductor layers 103 and 102a. The semiconductor layer 192 is of a same material and crystal structure as the semiconductor layer 101. In FIG. 23, the semiconductor layer 102a is a different semiconductor material than the semiconductor layer 101. In a particular example given herein, the semiconductor layer 101 includes silicon, whereas the semiconductor layer 102a includes silicon germanium. The semiconductor layer 103 also includes silicon germanium. However, the semiconductor layer 102a includes a different concentration of germanium than does the semiconductor layer 103 such that semiconductor layer 103 can be selectively etched with respect to the material of the semiconductor layer 102a.

In FIG. 24, the compound wafer 105 has been formed by flipping the wafer 100a and bonding the wafer 100a to the wafer 100b. In FIG. 24, the semiconductor substrate is a different material than the semiconductor substrate 102a. In a particular example given herein, the semiconductor substrate 102b includes silicon with a crystal orientation of 100, while the semiconductor layer 102a includes silicon germanium.

In FIG. 25, the semiconductor layers 101, 103, and 192 have been removed from the compound wafer 105. These layers can be removed using one or more etching processes substantially as described in relation to FIG. 1C.

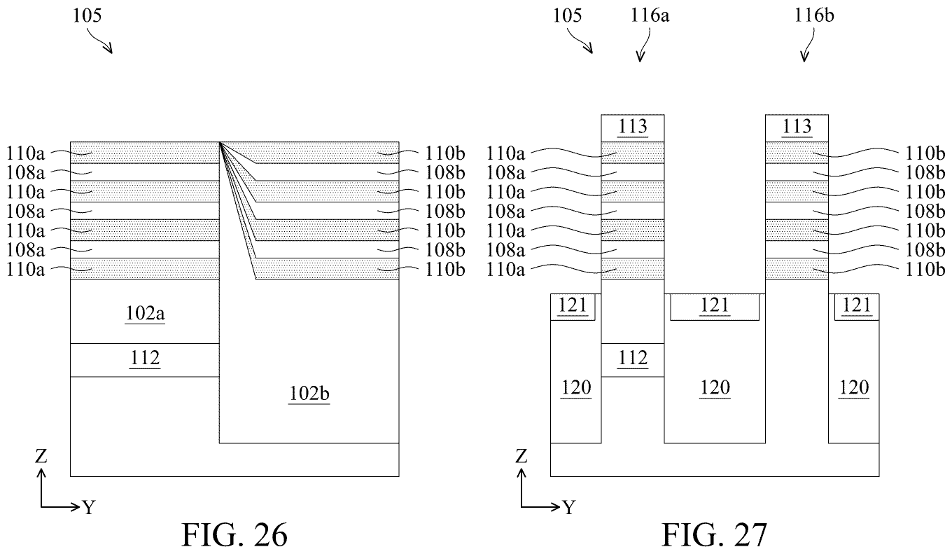

In FIG. 26, a stack 107a of semiconductor layers 108a and sacrificial semiconductor layers 110a have been grown epitaxially from the semiconductor substrate 102a and a stack 107b of semiconductor layers 108b and sacrificial semiconductor layers 110b have been grown epitaxially from the semiconductor substrate 102b, substantially as described in relation to FIGS. 5 and 6. However, in FIG. 26, the semiconductor layers 108a and 108b are different semiconductor materials. The sacrificial semiconductor layers 110a and 110b are also different semiconductor materials. In some embodiments, the semiconductor layers 108a are silicon germanium and will be utilized to form channels of PFET devices and the semiconductor layers 108b are silicon and will be utilized to form channels of NFET devices. In some embodiments, the sacrificial semiconductor layers 110a are silicon and the sacrificial semiconductor layers 110b are silicon germanium. Other materials can be utilized without departing from the scope of the present disclosure.

In FIG. 27, the fins 116a/b and the dielectric isolation structures 120 have been formed, substantially as described in relation to FIGS. 7A-8B.

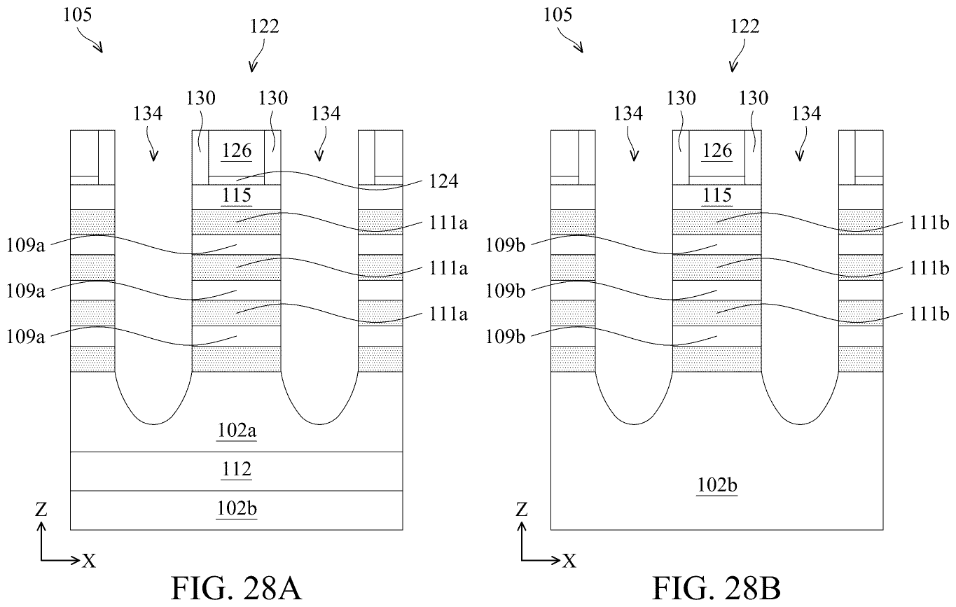

In FIGS. 28A and 28B, the sacrificial gate structures 122, and the gate spacer layers 130, and the source/drain trenches 134 have been formed, substantially as described in relation to FIGS. 9A-10C. The result is that stacks of channels 109a/b have been formed from the semiconductor layers 108a/b, sacrificial semiconductor nanostructures 111a/b have been formed from the sacrificial semiconductor layers 110a/b, and dielectric structures 115 have been formed from the hard mask layer 113.

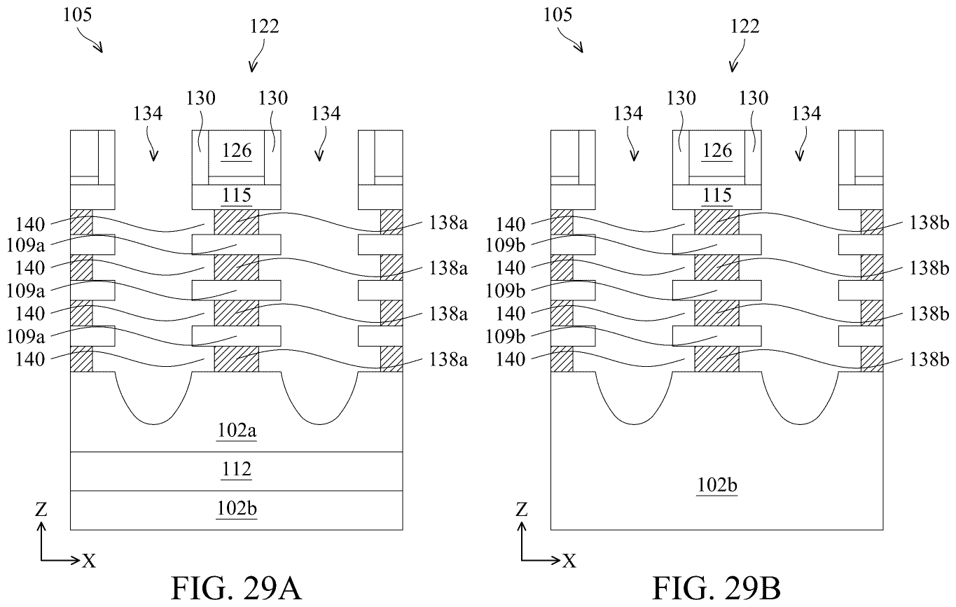

In FIGS. 29A and 29B, the sacrificial semiconductor nanostructures 111a/b have been replaced by sacrificial dielectric nanostructures 138a/b and recesses 140 have been formed, substantially as described in relation to FIGS. 11A-13B. In some embodiments, the sacrificial semiconductor nanostructures 111a and 111b are removed in separate steps due to their different semiconductor materials. The semiconductor nanostructures 111a can be removed by a first etching step while the NFET regions are covered by a patterned mask. The semiconductor nanostructures 111b can be removed and a second etching step while the PFET regions are covered by a patterned mask. The recesses 140 can be formed at the two locations in different etching steps as well.

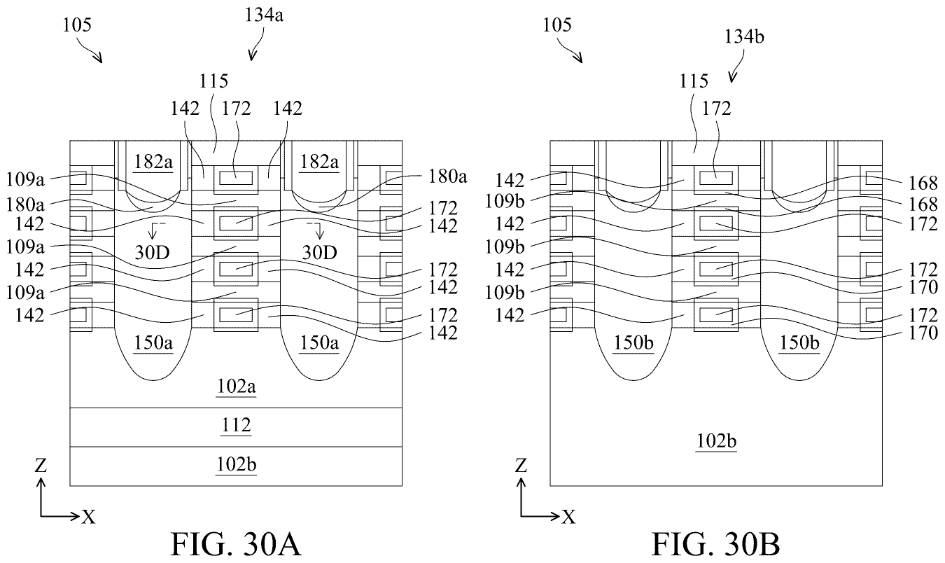

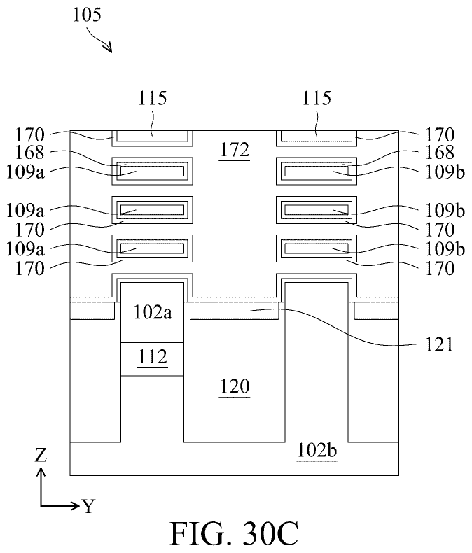

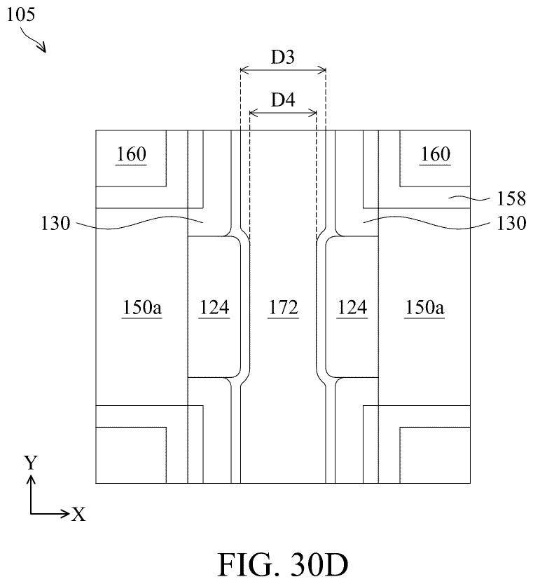

In FIGS. 30A-30D, formation of the transistors 134a/b is substantially complete, in accordance with some embodiments. In particular, source/drain regions 150a/b, silicide 180a/b, source/drain contacts 182a/b, the interfacial dielectric layer 168, the high-K gate dielectric layer 170, and the gate metal 172 have been formed substantially as described in relation to FIGS. 14A-17E. The channels 109a are a different semiconductor material than the channels 109b. In some embodiments, the channels 109a include silicon germanium suitable for the mobility of holes in PFET devices. In some embodiments, the channels 109b include silicon with a crystal orientation of 100, suitable for the mobility of electrons in NFET devices.

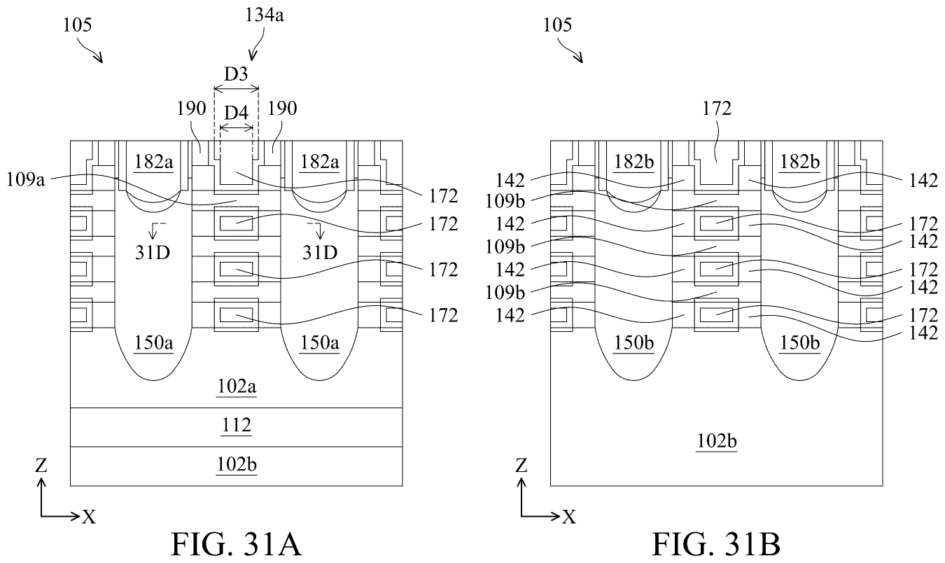

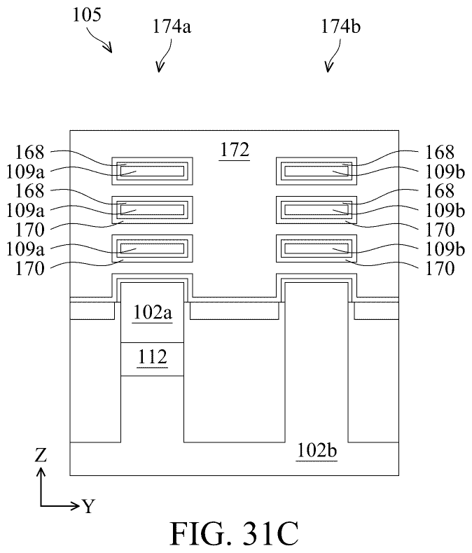

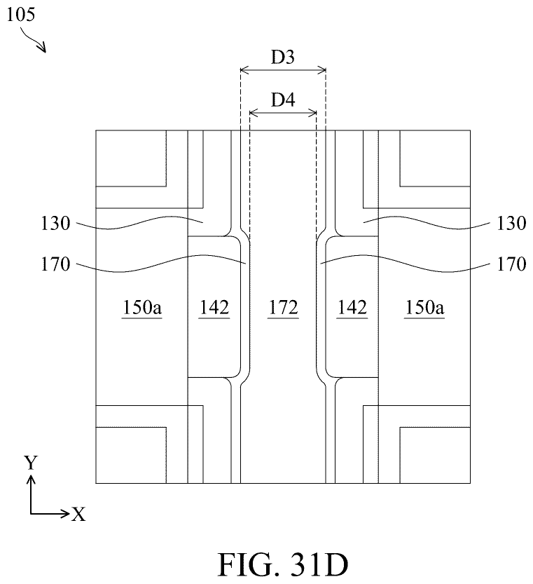

FIGS. 31A-31D are cross-sectional views of a wafer 105, in accordance with some embodiments. The wafer 105 includes transistors 134a including channels 109a of a first semiconductor material suitable for the mobility of holes in PFET devices, as described in relation to FIGS. 23-30D. The wafer 105 includes channels 109b of a second semiconductor material suitable for the mobility of electrons in NFET devices, as described in relation to FIGS. 23-30D. In FIGS. 31A-31D, hard mask remnants 190 have been formed from the dielectric structures 115, resulting in a T-shape gate metal 172, substantially as described in relation to FIGS. 18A-19D.

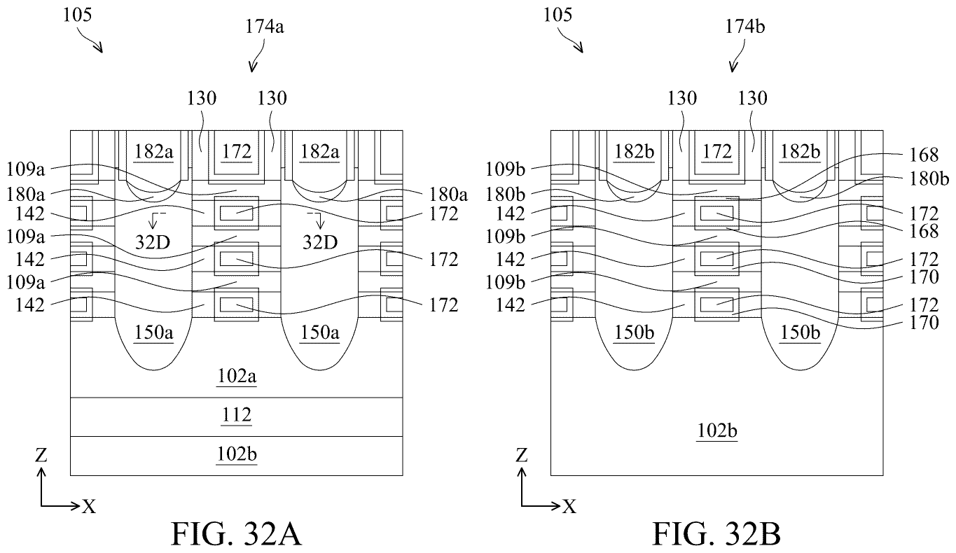

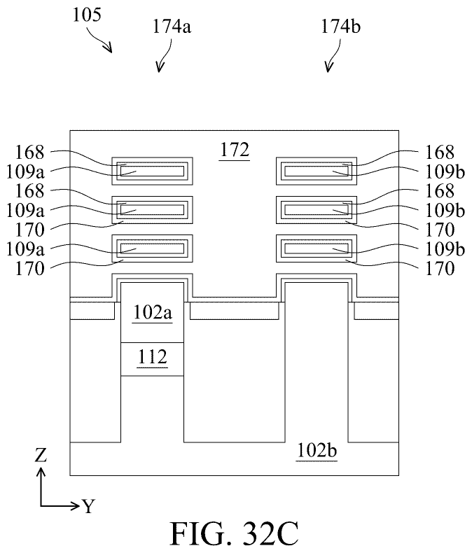

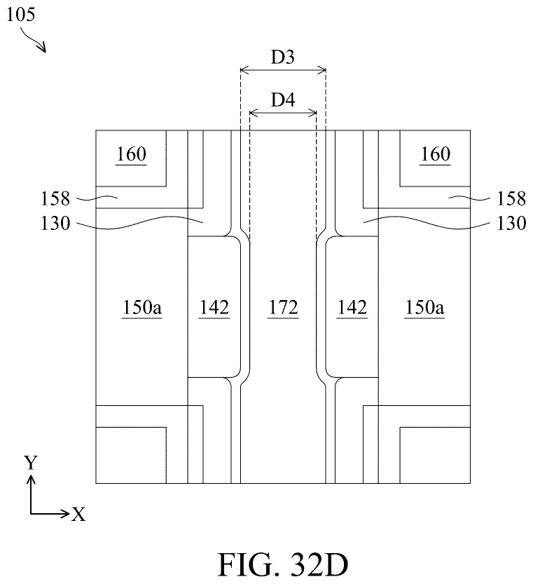

FIGS. 32A-32D are cross-sectional views of a wafer 105, in accordance with some embodiments. The wafer 105 includes transistors 134a including channels 109a of a first semiconductor material suitable for the mobility of holes in PFET devices, as described in relation to FIGS. 23-30D. The wafer 105 includes channels 109b of a second semiconductor material suitable for the mobility of electrons in NFET devices, as described in relation to FIGS. 23-30D. In FIGS. 32A-32D, the hard mask layer 113 and corresponding dielectric structures 113 are not formed, substantially as described in relation to FIGS. 20-22D.

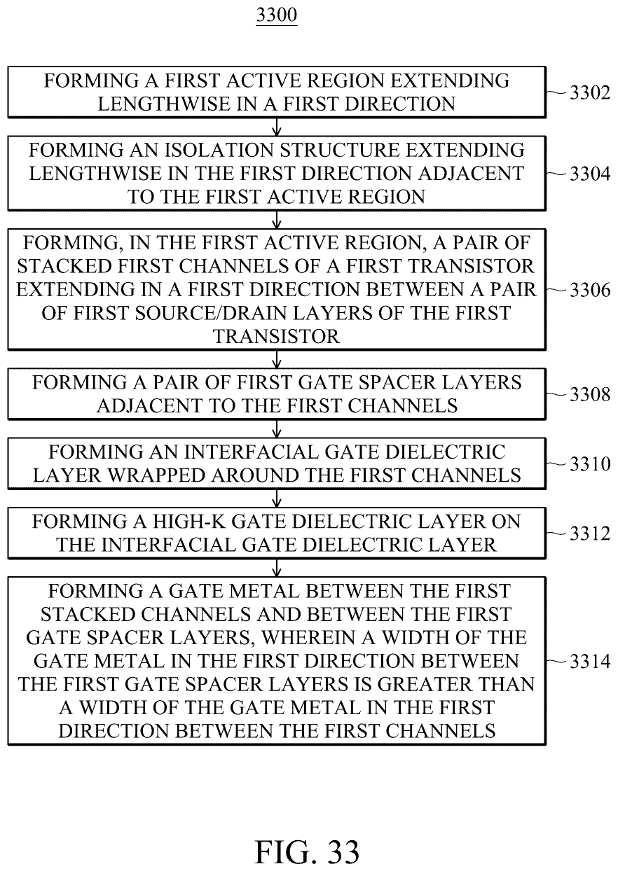

FIG. 33 is a flow diagram of a method 3300 for forming an integrated circuit, in accordance with some embodiments. The method 3300 can utilize systems, processes, components, and principles described in relation to FIGS. 1A-32D. At 3302, the method 3300 includes forming a first active region extending lengthwise in a first direction. One example of a first active region is the active region 116a of FIG. 8A. At 3304, the method 3300 includes forming an isolation structure extending lengthwise in the first direction adjacent to the first active region. One example of an isolation structure is the isolation structure 120 of FIG. 8A. At 3306, the method 3300 includes forming, in the first active region, a pair of stacked first channels of a first transistor extending in a first direction between a pair of first source/drain layers of the first transistor. One example of a first transistor is the transistor 174a of FIG. 17A. One example of stacked first channels are the channels 109a of FIG. 17A. One example of first source/drain regions are the source/drain regions 150a of FIG. 17A. At 3308, the method 3300 includes depositing a pair of first gate spacer layers adjacent to the first channels. One example of gate spacer layers are the gate spacer layers 130 of FIG. 17D. At 3310, the method 3300 includes depositing a sacrificial nanostructure between the pair of stacked first channels. One example of a sacrificial nanostructure is the sacrificial nanostructure 138 of FIG. 12A. At 3312, the method 3300 includes recessing ends of the sacrificial nanostructure such that a width of the sacrificial nanostructure in the first direction is less than a distance between the pair of first gate spacer layers in the first direction. At 3314, the method 3300 includes forming a pair of inner spacers adjacent to the ends of the sacrificial nanostructure. One example of inner spacers are the inner spacers 142 of FIG. 14A. At 3316, the method 3300 includes removing the sacrificial nanostructure after forming the pair of inner spacers. At 3318, the method 3300 includes depositing an interfacial gate dielectric layer wrapped around the first channels. One example of an interfacial gate dielectric layer is the interfacial gate dielectric layer 168 of FIG. 17A. At 3320, the method 3300 includes depositing a high-K gate dielectric layer on the interfacial gate dielectric layer. One example of a high-K gate dielectric layer is the high-K gate dielectric layer 170 of FIG. 17A. At 3322, the method 3300 includes depositing a gate metal between the first stacked channels and between the first gate spacer layers, wherein a width of the gate metal in the first direction between the first gate spacer layers is greater than a width of the gate metal in the first direction between the first channels based on recessing the ends of the sacrificial nanostructure. One example of a first gate metal is the gate metal 172 of FIG. 17A.

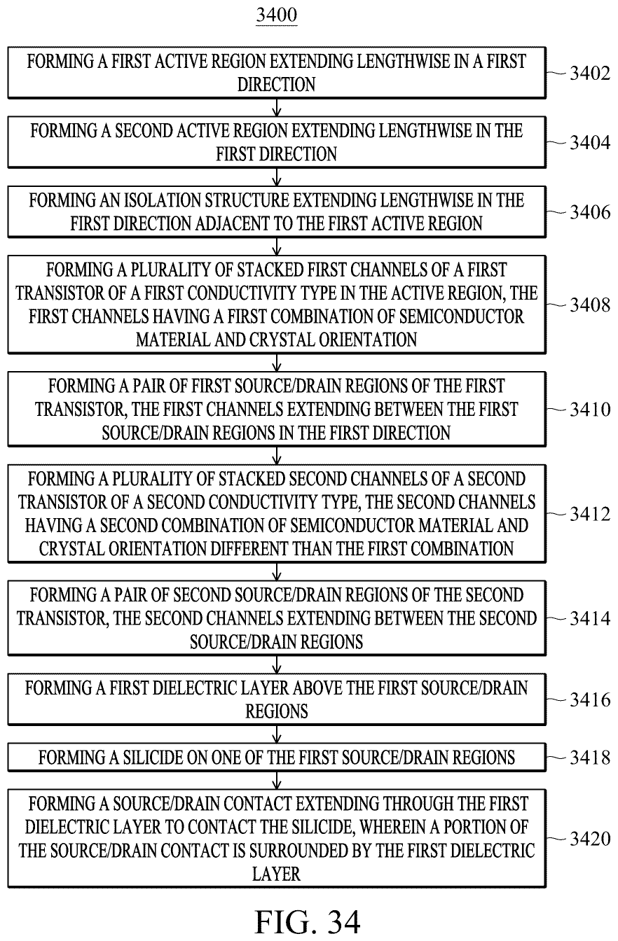

FIG. 34 is a flow diagram of a method 3400 for forming an integrated circuit, in accordance with some embodiments. The method 3400 can utilize systems, processes, components, and principles described in relation to FIGS. 1A-32D. At 3402, the method 3400 forming a stack of first semiconductor layers with one or more first epitaxial growth processes. One example of first semiconductor layers are the semiconductor layers 108a of FIG. 6. At 3404, the method 3400 includes forming a stack of second semiconductor layers with one or more second epitaxial growth processes. One example of first semiconductor layers are the semiconductor layers 108b of FIG. 6. At 3406, the method 3400 includes defining, from the stack of first semiconductor layers, a first semiconductor fin of a first active region extending lengthwise in a first direction. At 3408, the method 3400 includes defining, from the stack of second semiconductor layers, a second semiconductor fin of a second active region extending lengthwise in the first direction. One example of first and second semiconductor fins are the semiconductor fins 116a/b of FIG. 7A. At 3410, the method 3400 includes forming an isolation structure extending lengthwise in the first direction adjacent to the first active region. One example of an isolation structure is the isolation structure 118 of FIG. 8A. At 3412, the method 3400 includes defining, from the first semiconductor layers of the first semiconductor fin, a plurality of stacked first channels of a first transistor of a first conductivity type in the active region by forming first source/drain trenches in the first semiconductor fin, the first channels having a first combination of semiconductor material and crystal orientation. One example of first channels are the channels 109a of FIG. 17A. At 3414, the method 3400 includes forming first source/drain regions of the first transistor in the first source/drain trenches, the first channels extending between the first source/drain regions in the first direction. One example of first source/drain regions are the source/drain regions 150a of FIG. 17A. At 3416, the method 3400 includes defining, from the second semiconductor layers of the second semiconductor fin, a plurality of stacked second channels of a second transistor of a second conductivity type in the second active region by forming a second source/drain trenches in the second semiconductor fin, the second channels having a second combination of semiconductor material and crystal orientation different than the first combination. At 3418, the method 3400 includes forming a second source/drain region of the second transistor in the pair of second source/drain trenches, the second channels extending between the second source/drain regions. One example of second source/drain regions are the source/drain regions 150b of FIG. 17B. At 3420, the method 3400 includes forming a first dielectric layer above the first source/drain regions. At 3422, the method 3400 includes forming a silicide on one of the first source/drain regions. One example of a silicide is the silicide 180a of FIG. 17A. At 3424, the method 3400 includes forming a source/drain contact extending through the first dielectric layer to contact the silicide, wherein a portion of the source/drain contact is surrounded by the first dielectric layer. One example of a source/drain contact is the source/drain contact 157 of FIG. 30A.

Embodiments of the present disclosure provide an integrated circuit including transistors with improved electrical characteristics. Embodiments of the present disclosure provide transistors in which an inner gate length is shorter than an outer gate length. This is accomplished by forming deep recesses in sacrificial dielectric nanostructures for formation of inner spacers. After formation of the recesses, the length of the sacrificial semiconductor nanostructures is less than the width of the sacrificial gate structures. When the sacrificial gate structures and the sacrificial dielectric nanostructures are subsequently removed entirely and replaced with gate metals, the result is that the inner gate length is less than the outer gate length. Embodiments of the present disclosure also provide different crystal orientations for the channels of PFET and NFET devices.

The reduced inner gate length helps reduce the undesirable short channel effect. The different crystal orientations for the PFET channels and the NFET channels help ensure that both the NFET charge carriers and the PFET charge carriers have strong mobility. The result is integrated circuits with dense arrays of properly functioning transistors with good conduction and switching characteristics. This leads to better performing devices and higher wafer yields.

In some embodiments, a method includes forming a first active region extending lengthwise in a first direction, forming an isolation structure extending lengthwise in the first direction adjacent to the first active region, and forming, in the first active region, a pair of stacked first channels of a first transistor extending in a first direction between a pair of first source/drain layers of the first transistor. The method includes depositing a pair of first gate spacer layers adjacent to the first channels, depositing a sacrificial nanostructure between the pair of stacked first channels, and recessing ends of the sacrificial nanostructure such that a width of the sacrificial nanostructure in the first direction is less than a distance between the pair of first gate spacer layers in the first direction. The method includes forming a pair of inner spacers adjacent to the ends of the sacrificial nanostructure, removing the sacrificial nanostructure after forming the pair of inner spacers, depositing an interfacial gate dielectric layer wrapped around the first channels, depositing a high-K gate dielectric layer on the interfacial gate dielectric layer, and depositing a gate metal between the first stacked channels and between the first gate spacer layers. A width of the gate metal in the first direction between the first gate spacer layers is greater than a width of the gate metal in the first direction between the first channels based on recessing the ends of the sacrificial nanostructure.

In some embodiments, a method includes forming a stack of first semiconductor layers with one or more first epitaxial growth processes, forming a stack of second semiconductor layers with one or more second epitaxial growth processes, and defining, from the stack of first semiconductor layers, a first semiconductor fin of a first active region extending lengthwise in a first direction. The method incudes defining, from the stack of second semiconductor layers, a second semiconductor fin of a second active region extending lengthwise in the first direction, forming an isolation structure extending lengthwise in the first direction adjacent to the first active region, and defining, from the first semiconductor layers of the first semiconductor fin, a plurality of stacked first channels of a first transistor of a first conductivity type in the active region by forming first source/drain trenches in the first semiconductor fin, the first channels having a first combination of semiconductor material and crystal orientation. The method includes forming first source/drain regions of the first transistor in the first source/drain trenches, the first channels extending between the first source/drain regions in the first direction, defining, from the second semiconductor layers of the second semiconductor fin, a plurality of stacked second channels of a second transistor of a second conductivity type in the second active region by forming a second source/drain trenches in the second semiconductor fin, the second channels having a second combination of semiconductor material and crystal orientation different than the first combination, and forming second source/drain regions of the second transistor in the pair of second source/drain trenches, the second channels extending between the second source/drain regions. The method includes forming a first dielectric layer above the first source/drain regions, forming a silicide on one of the first source/drain regions, and forming a source/drain contact extending through the first dielectric layer to contact the silicide, wherein a portion of the source/drain contact is surrounded by the first dielectric layer.

In some embodiments, a device includes a substrate, a first active region disposed over the substrate and extending lengthwise along a first lateral direction, a second active region disposed over the substrate and extending lengthwise along a first lateral direction, and an isolation structure disposed over the substrate between the first active region and the second active region and extending in the first direction alongside the first active region. The device includes a first transistor including first source/drain regions in the first active region and stacked first channels in the first active region extending in the first lateral direction between the pair of first source/drain regions such that sidewalls of the first channels interface the first source/drain regions. The device includes a second transistor including second source/drain regions in the second active region and stacked second channels in the second active region extending in the first lateral direction between the pair of second source/drain regions such that sidewalls of the second channels interface the second source/drain regions. The device includes gate spacer layers adjacent to the first channels and extending in a second lateral direction transverse to the first lateral direction and a gate metal having a first length in the first direction between the pair of stacked first channels and a second length in the first direction between the pair of gate spacer layers, wherein the first length is different than the second length.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first active region extending lengthwise in a first direction;
forming an isolation structure extending lengthwise in the first direction adjacent to the first active region;
forming, in the first active region, a pair of stacked first channels of a first transistor extending in a first direction between a pair of first source/drain layers of the first transistor;
depositing a pair of first gate spacer layers adjacent to the first channels;
depositing a sacrificial nanostructure between the pair of stacked first channels;
recessing ends of the sacrificial nanostructure such that a width of the sacrificial nanostructure in the first direction is less than a distance between the pair of first gate spacer layers in the first direction;
forming a pair of inner spacers adjacent to the ends of the sacrificial nanostructure;
removing the sacrificial nanostructure after forming the pair of inner spacers;
depositing an interfacial gate dielectric layer wrapped around the first channels;
depositing a high-K gate dielectric layer on the interfacial gate dielectric layer; and
depositing a gate metal between the first stacked channels and between the first gate spacer layers, wherein a width of the gate metal in the first direction between the first gate spacer layers is greater than a width of the gate metal in the first direction between the first channels based on recessing the ends of the sacrificial nanostructure.

2. The method of claim 1, comprising:
forming a second active region extending lengthwise in the first direction;
forming, in the second active region, a pair of stacked second channels of a first transistor extending in a first direction between a pair of first source/drain layers of the first transistor;
forming a pair of second gate spacer layers adjacent to the second channels;
forming the interfacial gate dielectric layer wrapped around the second channels;
forming the high-K gate dielectric layer on the interfacial gate dielectric layer around the second channels; and
forming the gate metal between the second stacked channels and between the second gate spacer layers, wherein a width of the gate metal in the first direction between the second gate spacer layers is greater than a width of the gate metal in the first direction between the second channels.

3. The method of claim 1, wherein the first transistor is an N-type transistor and the second transistor is a P-type transistor.

4. The method of claim 3, wherein the first channels are a same semiconductor material as the second channels, wherein the first channels have a first crystal orientation and the second channels have a second crystal orientation.

5. The method of claim 3, wherein the first channels are a different semiconductor material than the second channels.

6. The method of claim 5, wherein the first channels are silicon and the second channels are silicon germanium.

7. The method of claim 1, comprising forming a dielectric structure above the first channels having lateral dimension approximately equal to lateral dimensions of the first channels.

8. The method of claim 7, comprising performing a chemical mechanical planarization process to make a top surface of the gate metal coplanar with a top surface of the dielectric structure.

9. The method of claim 7, further comprising forming hard mask remnants above the first channels by removing a central portion of the dielectric structure, wherein a width of the gate metal in the first direction between the hard mask remnants is greater than the width of the gate metal in the first direction between the first channels.

10. The method of claim 9, wherein the first gate spacer layers are on the hard mask remnants.

11. The method of claim 9, wherein the gate metal has a T shape above the highest first channel.

12. A method, comprising:
forming a stack of first semiconductor layers with one or more first epitaxial growth processes;
forming a stack of second semiconductor layers with one or more second epitaxial growth processes;
defining, from the stack of first semiconductor layers, a first semiconductor fin of a first active region extending lengthwise in a first direction;
defining, from the stack of second semiconductor layers, a second semiconductor fin of a second active region extending lengthwise in the first direction;
forming an isolation structure extending lengthwise in the first direction adjacent to the first active region;
defining, from the first semiconductor layers of the first semiconductor fin, a plurality of stacked first channels of a first transistor of a first conductivity type in the active region by forming first source/drain trenches in the first semiconductor fin, the first channels having a first combination of semiconductor material and crystal orientation;
forming first source/drain regions of the first transistor in the first source/drain trenches, the first channels extending between the first source/drain regions in the first direction;
defining, from the second semiconductor layers of the second semiconductor fin, a plurality of stacked second channels of a second transistor of a second conductivity type in the second active region by forming a second source/drain trenches in the second semiconductor fin, the second channels having a second combination of semiconductor material and crystal orientation different than the first combination;
forming second source/drain regions of the second transistor in the pair of second source/drain trenches, the second channels extending between the second source/drain regions;
forming a first dielectric layer above the first source/drain regions;
forming a silicide on one of the first source/drain regions; and
forming a source/drain contact extending through the first dielectric layer to contact the silicide, wherein a portion of the source/drain contact is surrounded by the first dielectric layer.

13. The method of claim 12, wherein the first channels are a first semiconductor material and have a first crystal orientation, wherein the second channels are the first semiconductor material and have a second crystal orientation different than the first crystal orientation.

14. The method of claim 13, further comprising:
forming a composite wafer by bonding a first wafer having a first semiconductor substrate of the first semiconductor material having the first crystal orientation to a second wafer having a second semiconductor substrate of the first semiconductor material having the second crystal orientation, the first semiconductor substrate being above the second semiconductor substrate in the composite wafer;
epitaxially growing a plurality of stacked first semiconductor layers of the first semiconductor material and the first crystal orientation from the first semiconductor substrate;
exposing a portion of the second semiconductor substrate via an etching process;
epitaxially growing a plurality of stacked second semiconductor layers of the first semiconductor material and the second crystal orientation from the second semiconductor substrate;
forming the first channels from the first semiconductor layers; and
forming the second channels from the second semiconductor layers.

15. The method of claim 12, wherein the first channels are a first semiconductor material, wherein the second channels are a semiconductor material than the first semiconductor material.

16. The method of claim 15, further comprising:
forming a composite wafer by bonding a first wafer having a first semiconductor substrate of the first semiconductor material to a second wafer having a second semiconductor substrate of the second semiconductor material, the first semiconductor substrate being above the second semiconductor substrate in the composite wafer;
epitaxially growing a plurality of stacked first semiconductor layers of the first semiconductor material from the first semiconductor substrate;
exposing a portion of the second semiconductor substrate via an etching process;
epitaxially growing a plurality of stacked second semiconductor layers of the second semiconductor material from the second semiconductor substrate;
forming the first channels from the first semiconductor layers; and
forming the second channels from the second semiconductor layers.

17. A device, comprising:
a substrate;
a first active region disposed over the substrate and extending lengthwise along a first lateral direction;
a second active region disposed over the substrate and extending lengthwise along a first lateral direction;
an isolation structure disposed over the substrate between the first active region and the second active region and extending in the first direction alongside the first active region;
a first transistor including:
first source/drain regions in the first active region; and
stacked first channels in the first active region extending in the first lateral direction between the pair of first source/drain regions such that sidewalls of the first channels interface the first source/drain regions;
a second transistor including:
second source/drain regions in the second active region; and
stacked second channels in the second active region extending in the first lateral direction between the pair of second source/drain regions such that sidewalls of the second channels interface the second source/drain regions;
gate spacer layers adjacent to the first channels and extending in a second lateral direction transverse to the first lateral direction; and
a gate metal having a first length in the first direction between the pair of stacked first channels and a second length in the first direction between the pair of gate spacer layers, wherein the first length is different than the second length.

18. The device of claim 17, wherein the first channels have a first semiconductor material and the second channels have a second semiconductor material different than the first semiconductor material.

19. The device of claim 17, wherein the first channels and the second channels are of a same semiconductor material, wherein the first channels have a first crystal orientation and the second channels have a second crystal orientation different than the first crystal orientation.

20. The device of claim 16, further comprising a hardmask nanostructure over the first channels having a same dimension in the first and second lateral directions as the first channels, wherein the gate metal has the first length between the dielectric structure and a top first channel.
